(19) United States
(12) Patent Application Publication
(10) Pub. No.: US 2026/0160830 A1
(43) Pub. Date: Jun. 11, 2026

(54) CIRCUIT FOR DETECTING SHORT CIRCUITS IN FULL-BRIDGE CLASS-D AMPLIFIERS AND CORRESPONDING METHOD

(71) Applicant: STMicroelectronics International N.V., Geneva (CH)

(72) Inventors: Giovanni GONANO, Milano (IT); Davide Luigi BRAMBILLA, Segrate (MI) (IT)

(73) Assignee: STMicroelectronics International N.V., Geneva (CH)

(21) Appl. No.: 19/407,456

(22) Filed: Dec. 3, 2025

(30) Foreign Application Priority Data
Dec. 6, 2024 (IT) 102024000027702

(51) Int. Cl. G01R 31/52; H03F 3/217

(52) U.S. Cl. CPC G01R 31/52; H03F 3/2173; H03F 2200/03; H03F 2200/171; H03F 2200/351; H03F 2200/462; H03F 2200/471; H03F 2200/481

(57) ABSTRACT

A full-bridge class-D amplifier includes: a first branch with a first high-side switch and a first low-side switch coupled at a first output node in series between a supply voltage and ground; and a second branch with a second high-side switch and a second low-side switch coupled at a second output node in series between the supply voltage ground. A circuit for detecting electrical short circuits in the amplifier includes: a measuring circuit configured to provide a first measure of high-side switch operation in one of the branches and a second measure of low-side switch operation in the other of the branches; a checking circuit configured to determine an imbalance between the first and second measures to generate an imbalance signal; and a detection circuit configured to presence of an electrical short circuit in response to the imbalance signal.

### PRIORITY CLAIM

This application claims the priority benefit of Italian Application for U.S. Pat. No. 102024000027702 filed on Dec. 6, 2024, the content of which is hereby incorporated by reference in its entirety to the maximum extent allowable by law.

### TECHNICAL FIELD

The description relates to circuits for detecting short circuits in full-bridge class-D amplifiers.

One or more embodiments can be related to circuits for detecting short circuits in full-bridge class-D amplifiers via imbalance checks.

### BACKGROUND

Known car radio class-D amplifiers comprise a full-bridge output stage, usually coupled with two LC filters, and a single supply, usually consisting in the car battery.

FIG. 1 illustrates a known structure 5 of a full-bridge class-D output stage having a short circuit applied on the output.

The full-bridge output stage of the structure 5 illustrated in FIG. 1 comprises: a first high-side switch HP, for instance, implemented via a first Field-Effect Transistor (FET), coupled between the supply, for instance, the car battery, configured to provide a voltage VCC and a first output node Out_{P} of the output stage; a second high-side switch HM, for instance, implemented via a second FET, coupled between the supply, for instance, the car battery, configured to provide the voltage VCC and a second output node Out of the output stage; a first low-side switch LP, for instance, implemented via a third FET, coupled between such first output node Out_{P} of the output stage and a ground node GND; and a second low-side switch LM, for instance, implemented via a fourth FET, coupled between such second output node Out_{M} of the output stage and the ground node GND.

Such output stage may be coupled with two LC filters: a first LC filter Lfilt_{P} and a second LC filter Lfilt_{M}.

The first LC filter Lfilt_{P} comprises: a first inductor L1_{P} coupled between the first output node Out_{P} of the output stage and a first output node of the LC filtering stage OutLC_{P}; and a first capacitor Cp coupled between the first output node of the LC filtering stage OutLC_{P} and the ground node GND.

The second LC filter Lfilt_{M} comprises: a second inductor L2_{M} coupled between the second output node Out of the output stage and a second output node of the LC filtering stage OutLC_{M}; and a second capacitor CM coupled between the second output node of the LC filtering stage OutLC_{M} and the ground node GND.

It is noted that a load LD may be coupled between the first output node of the LC filtering stage OutLC_{P} and the second output node of the LC filtering stage OutLC_{M}.

The first high-side switch HP, the second high-side switch HM, the first low-side switch LP, and the second low-side switch LM may be implemented using both N-DMOS (“double-diffused MOS transistor” of N type), N or P-DMOS kind, GaN FETs (“Gallium Nitride FETs”), or any other available semiconductor technology.

The output of power audio amplifiers and other devices operating with Pulse-Width Modulation (PWM) output stages, such as the full-bridge output stage illustrated in FIG. 1, is to be protected against short circuits.

For instance, such short circuits may be due to connections of one of the output terminals (after the LC filters), for instance, either the first output node of the LC filtering stage OutLC_{P} (as illustrated in FIG. 1) or the second output node of the LC filtering stage OutLC_{M}, which are usually coupled to a load LD in normal driving conditions (that is, in absence of short circuit) to the ground node GND, to the supply configured to provide the voltage VCC, or to another output different from the load LD.

For example, such a connection may be performed: via an impedance ZS (such as a resistance) having a (even very) low value, for example, an impedance ZS in the order of few milli-ohm (“mΩ”); or via RL series, that is, a resistor-inductor circuit having a resistor R coupled in series with an impedance L.

Further short circuits may be due to connections of the first output node Out_{P} or the second output node Out_{M} (before the LC filters) to the ground node GND, to the supply configured to provide the voltage VCC, or to another output.

In such a case, a time related to the rising of the current flowing in the output stage may depend on the impedance ZS of the short circuit connection.

For example, such further short circuits may be present in filter-less applications (also used in audio systems), that is, in full-bridge output stage not coupled with LC filters, where the first output node Out_{P} and the second output node Out_{M} are directly driving the load LD.

The detection of such short circuits in full-bridge class-D amplifiers is usually made by comparing a sensing signal such as a sensed voltage proportional to an output current used to drive the load LD (such as a Vds voltage drop of one of the transistors or a voltage drop on a resistor comprised in the output stage) with a reference signal such as a reference voltage (for instance, obtained by injecting a reference current in an element matched with the considered transistor or the considered resistor).

FIG. 2 illustrates a known circuit 10 that detects output current overloads SD by sensing a Vds voltage, that is, the FET absolute voltage between a current-absorbing (drain) terminal and a current-supplying (source) terminal, of a low-side transistor LM or LP of the full-bridge class-D output stage.

Such sensed Vds voltage of the low-side transistor LM or LP of the full-bridge class-D output stage is the considered sensing signal Vₛₑₙₛ proportional to the output current Iₒᵤₜ used to drive the load LD.

Such low-side transistor LM or LP illustrated in FIG. 2 is driven by a driver 102 via its control (gate) terminal and have the output current Iₒᵤₜ used to drive the load LD flowing between its current-absorbing (drain) terminal and its current-supplying (source) terminal.

The Vds voltage of the low-side transistor LM or LP of the full-bridge class-D output stage Vₛₑₙₛ is sensed by coupling the current-absorbing (drain) terminal of such low-side transistor LM or LP to a first input terminal of a comparator 100.

A second input terminal of the comparator 100 is configured to receive a reference voltage V_{ref}, for instance, corresponding to the Vds voltage of a reference transistor L_{ref} (having a width value W_{ref} and a channel length value Lₘᵢₙ) matched with the low-side transistor LM or LP (having a width value Wₘₐᵢₙ, for instance, usually 100 times bigger than the value W_{ref}, and the same channel length value Lₘᵢₙ) and coupled between the supply at the voltage VCC and ground GND, such reference transistor L_{ref} having an injected reference current I_{ref} flowing between its current-absorbing (drain) terminal and its current-supplying (source) terminal.

It is noted that such reference current I_{ref} corresponds to a maximum current allowed to flow in such reference transistor L_{ref}, and, since such reference transistor L_{ref} is matched with the low-side transistor LM or LP, in the low-side transistor LM or LP.

Therefore, the reference voltage V_{ref} is acting as a threshold corresponding to a maximum Vds voltage allowed in the reference transistor L_{ref} and, again since such reference transistor L_{ref} is matched with the low-side transistor LM or LP, in the low-side transistor LM or LP.

Hence, the comparator 100 is configured to: receive the sensed Vds voltage Vₛₑₙₛ (at the first input terminal) and the reference voltage V_{ref} (at the second input terminal); compare such voltages in order to determine whether the sensed Vds voltage Vₛₑₙₛ is higher than the reference voltage V_{ref} acting as threshold (that is, the maximum Vds voltage allowed); and output a logic variable having, for instance, a high logic level when such sensed Vds voltage Vₛₑₙₛ is higher than the reference voltage V_{ref} and a low logic level otherwise.

The logic variable is provided to a logic AND block 104 configured to receive such logic variable and a signal from the driver 102, for instance, having a high logic level if the driver 102 is driving the low-side transistor LM or LP to a conductive state and a low logic level otherwise.

Therefore, such logic AND block 104 is configured to detect a short circuit, for instance, by providing as output a short detection signal SD set to a high logic level, if the logic variable indicates that the sensed Vds voltage Vₛₑₙₛ is higher than the reference voltage V_{ref} (that is, than the maximum Vds voltage allowed) and if the signal from the driver 102 indicates that such driver 102 is driving the low-side transistor LM or LP to a conductive state.

It is noted that the logic variable indicates that the sensed Vds voltage Vₛₑₙₛ is higher than the reference voltage V_{ref} in response to the current provided as output by the full-bridge class-D amplifier Iₒᵤₜ being equal to a maximum current allowed to flow in such full-bridge class-D amplifier I_{OCP}.

The maximum current allowed to flow in such full-bridge class-D amplifier I_{OCP} may be obtained using the following equation:

$${I}_{OCP} = {I}_{ref} * ( \frac{{W}_{main}}{{W}_{ref}} )$$

wherein I_{ref} is the reference current described above, Wₘₐᵢₙ is the width value of the low-side transistor LM or LP, and W_{ref} is the width value of the reference transistor L_{ref}.

In response to the logic AND block 104 detecting a short circuit, protective measures are enabled in order to prevent the full-bridge output stage to operate in non-safe operative conditions. For instance, the full-bridge output stage can be put in a 3-state condition or a cycle-by-cycle protection can be activated in order to reduce the current flowing in such output stage.

As an alternative to the Vds sensing described above, it is possible to sense the voltage drop on the source metallization of a transistor, for instance, a DMOS transistor, comprised in the full-bridge class-D amplifier. In such a case, the voltage drop can be used as voltage signal for current sensing and current reference measurement.

A problem of traditional over-current protections (OCP) such as the known solution of FIG. 2 is that the output current Iₒᵤₜ used to drive the load LD provided by the full-bridge output stage has to reach the maximum current allowed (usually corresponding to maximum absolute ratings), that is, the reference current I_{ref} described above, to detect short circuits conditions, therefore, the full-bridge class-D amplifier output stage is led to operate close to non-safe operative conditions.

Therefore, solutions according to FIG. 2 have to react (very) quickly in order to prevent that the output current Iₒᵤₜ used to drive the load LD rises to dangerous values, leading the full-bridge output stage to operate in non-safe operative conditions.

It is noted that solutions according to FIG. 2 are used in applications such as car radio amplifiers supplied with a battery, for instance, at about 14.4 V (volt), where the short circuit protection is required as a standard.

In case of systems having a higher supply voltage, for instance, up to about 48 V (volt), a standard for short circuit detection is not available and solutions according to FIG. 2 may not enable the short circuit protection measures in time, that is, before the entering of the full-bridge output stage in a non-safe operative condition.

Usually, in such cases, some deviation from a fully compliant short circuit protection is accepted since the occurrence of a destructive event at the critical conditions (for instance, at high supply voltage, high temperature, or the like) might be judged low enough by the customer.

In fact, in applications such as car radio amplifiers supplied with the higher supply voltage, such testing comprises, for example, connecting one of the outputs of the full-bridge output stage to the supply at the voltage VCC or to ground GND along the whole supply voltage range (that is, for voltages comprised between zero and the considered higher supply voltage), at several driving conditions, considering different impedances, and at different temperatures.

Therefore, known solutions do not provide an acceptable tradeoff between maximum operative conditions and reliable short circuit protection in applications having higher supply voltages, that is, supply voltages higher than a battery voltage, for instance, supply voltages above 14.4V.

Hence, solutions to simplify the provision of a reliable short circuit protection even for supply voltages having high values, for instance, values above 14.4V (volt), would be beneficial in order to improve safety and prevent dangerous or faulty conditions.

There is accordingly a need in the art to contribute in providing solutions that facilitate the provision of a reliable short circuit protection even for supply voltages having high values in order to improve safety and prevent dangerous or faulty conditions in full-bridge class-D amplifiers.

### SUMMARY

One or more embodiments concern a circuit for detecting short circuits in full-bridge class-D amplifiers.

One or more embodiments concern a corresponding method.

Solutions as described herein address the previously described limitation via a circuit for detecting short circuits in full-bridge class-D amplifiers configured to: check for the presence of imbalances between measures related to a high-side switch of a branch of the full-bridge and measures related to the low-side switch of the other branch of such full-bridge; and in response to the checking operation indicating the presence of an imbalance, detecting the presence of a short circuit.

Therefore, solutions as described herein relates to a circuit for detecting electrical short circuits in a full-bridge class-D amplifier.

The full-bridge class-D amplifier comprises: a first branch comprising a first high-side switch configured to be coupled between a supply voltage and a first output node and a first low-side switch configured to be coupled between such first output node and ground; and a second branch comprising a second high-side switch configured to be coupled between such supply voltage and a second output node and a second low-side switch configured to be coupled between such second output node and ground.

The circuit according to solutions as described herein comprises: a measuring circuit configured to provide: a first measure of a first operating characteristic, for instance, a current, a voltage, or a time delay, of the high-side switch comprised in one of the first branch and the second branch of the full-bridge class-D amplifier; and a second measure of a second operating characteristic, for instance, a current, a voltage, or a time delay, of the low-side switch comprised in the other of the first branch and the second branch of the full-bridge class-D amplifier; a checking circuit configured to receive from the measuring circuit the first measure and the second measure and to provide an imbalance signal indicative of the presence of imbalance between such first measure and such second measure; and a detection circuit configured to receive from the checking circuit such imbalance signal and to detect the presence of an electrical short circuit in response to such imbalance signal indicating the presence of imbalance between such first measure and such second measure.

Solutions as described herein may be implemented via different approaches.

A first approach comprises detecting short circuit conditions based on current measurements.

In solutions according to such first approach, a current sensor is added for each of the four switches HP, LP, HM, and LM of the full-bridge.

A short circuit to the supply voltage or to ground can be detected when an imbalance between a current measured in a high-side switch of a branch of the full-bridge, that is, either HP or HM, and a current measured in the low-side switch of the other branch of the full-bridge, that is, either LM or LP respectively, is present.

The current sensors may be implemented in different ways.

For instance, a first way of implementing the current sensors comprises using a reference voltage as reference for a flash ADC and converting a sensed voltage proportional to the current flowing in a respective switch via such flash ADC. In such a case, an imbalance can be detected when the converted value for two different switches that are in a conductive state is above a threshold.

For instance, a second way of implementing such current sensors comprises level shifting to a common internal voltage or to ground and comparing sensed voltages proportional to currents flowing in respective switches that are in a conductive state. In such a case, an imbalance can be detected when the difference between the two sensed voltages is above a threshold.

A second approach comprises again detecting short circuit conditions based on current measurements.

In solutions according to such second approach, a current sensor is placed on the output of each of the two half-bridges.

In such a case, a short circuit to the supply voltage or to ground can be detected when an imbalance between the currents measured in the two half-bridges is present.

In solutions according to the second approach, the current sensors may be made by shunt resistors or by Hall effects.

A further approach comprises detecting short circuit conditions based on time measurements.

Solutions according to such further approach comprise measuring at each Pulse-Width Modulation (PWM) cycle (such PWM cycle being the cycle of a PWM signal generated for driving the half-bridges comprised in the full-bridge via respective drivers configured to operate respective switches comprised in such half-bridges) the following current dependent time delays, corresponding to time laps between input signals provided to drivers coupled to respective half-bridges comprised in the full-bridge and PWM output signals provided by the branches (that are, half-bridges) of such full-bridge: a first time delay indicative of a delay from a rising of an input signal provided to drivers related to a branch of the full-bridge (that is, to a half-bridge of the full-bridge) to a corresponding rising of the PWM output signal provided as output by such branch of the full-bridge, for instance, by a high-side switch of such branch; a second time delay indicative of a delay from a falling of an input signal provided to the drivers related to such branch of the full-bridge (that is, to such half-bridge of the full-bridge) to a corresponding falling of the PWM output signal provided as output by such branch of the full-bridge, for instance, by the low-side switch of such branch; a third time delay indicative of a delay from a rising of an input signal provided to drivers related to the other branch of the full-bridge (that is, to the other half-bridge of the full-bridge) to a corresponding rising of the PWM output signal provided as output by such other branch of the full-bridge, for instance, by a high-side switch of such other branch; and a fourth time delay indicative of a delay from a falling of an input signal provided to the drivers related to such other branch of the full-bridge (that is, to such other half-bridge of the full-bridge) to a corresponding falling of the PWM output signal provided as output by such other branch of the full-bridge, for instance, by the low-side switch of such other branch.

In addition, solutions according to such further approach comprise detecting a short circuit to the supply voltage or to ground when an imbalance between the third time delay and the second time delay or the first time delay and the fourth time delay is present.

It is noted that in class “BD” modulation the time delays may be stored in a capacitor by voltage conversion and then elaborated, while in class “AD” modulation such time delays can be directly elaborated.

Hence, solutions as described herein facilitate providing reliable short circuit detection and protection features. For instance, solutions as described herein facilitate providing reliable short circuit detection also in the presence of supply voltages having high values, for instance, values above 14.4V (volt). Therefore, solutions as described herein may improve the trade-off between safety and performance (that is, maximum operative supply voltage and maximum load current) and may prevent dangerous or faulty conditions due to the presence of such short circuits in full-bridge class-D amplifiers.

### BRIEF DESCRIPTION OF THE DRAWINGS

One or more embodiments will now be described, by way of example only, with reference to the annexed figures, wherein:

FIG. 1 illustrates, as previously described, a known structure of a full-bridge class-D output stage having a short circuit applied on the output;

FIG. 2 illustrates, as previously described, a known circuit that detects output current overloads by sensing the Vds voltage of a low-side transistor of the full-bridge class-D output stage;

FIG. 3 illustrates a first exemplary circuit for detecting short circuits based on current sensing;

FIG. 4 illustrates an exemplary current sensing block used in embodiments according to FIG. 3 and configured to perform a conversion operation via an Analog-to-Digital Converter (ADC) circuit;

FIG. 5 illustrates a further exemplary current sensing block used in embodiments according to FIG. 3 and configured to perform a comparison operation via a comparator block;

FIG. 6 illustrates a second exemplary circuit for detecting short circuits based on current sensing;

FIGS. 7A and 7B illustrate exemplary current sensing blocks used in embodiments according to FIG. 6;

FIG. 8 illustrates an exemplary circuit for managing Pulse-Width Modulation (PWM) signals used to drive a full-bridge class-D amplifier;

FIG. 9 illustrates time delay behaviors as a function of an output current provided by the full-bridge class-D amplifier to a load coupled therewith;

FIGS. 10A and 10B illustrate a full-bridge class-D amplifier having a short circuit to ground;

FIGS. 11A and 11B illustrate a full-bridge class-D amplifier having a short circuit to the supply voltage;

FIGS. 12A, 12B, and 12C illustrate behaviors of fronts of signals provided as output by the full-bridge class-D amplifier;

FIG. 13 illustrates a third exemplary circuit for detecting short circuits based on time measurements in class “BD” modulation conditions; and

FIG. 14 illustrates a further exemplary circuit for detecting short circuits based on time measurements in class “AD” modulation conditions.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular configurations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

As previously described, solutions as disclosed herein facilitate providing reliable short circuit detection and protection features even in presence of supply voltages having high values, for instance, values above 14.4V (volt), hence, improving the trade-off between safety and performance (that is, maximum operative supply voltage and maximum load current) and preventing dangerous or faulty conditions due to the presence of such short circuits.

Therefore, solutions as described herein aim at improving the robustness of full-bridge class-D amplifiers, for instance, used in car radio systems, to short circuits to the supply voltage VCC, to ground GND, or to a battery voltage (if different from the supply voltage VCC).

In addition, solutions as described herein can advantageously discriminate in a (even very) short time, for instance, in few periods of a Pulse-Width Modulation (PWM) signal used to drive a full-bridge class-D amplifier, the presence of a short circuit to ground GND or to the supply voltage VCC with respect to the normal driving conditions, that is, to driving conditions without short circuits.

Such detection of the presence of a short circuit can be performed independently from the value of an output current Iₒᵤₜ provided by the full-bridge class-D amplifier to a load LD coupled therewith, that is, independently from the value of the output current Iₒᵤₜ with respect to a maximum current allowed to flow in the switches of the full-bridge.

Hence, the short circuit can be detected also in presence of output current Lout values that are lower than the maximum current allowed to flow in transistors of the full-bridge class-D amplifier, such maximum current allowed to flow I_{OCP} being obtained via the previously described equation, that is, by dividing the width value of a transistor comprised in the full-bridge class-D amplifier Wₘₐᵢₙ by the width value of the reference transistor L_{ref} W_{ref}, obtaining the value

$$\frac{{W}_{main}}{{W}_{ref}} ,$$

and by multiplying such value

$$\frac{{W}_{main}}{{W}_{ref}}$$

by the value of the previously described reference current I_{ref}.

It is noted that such maximum current allowed to flow in transistors of the full-bridge class-D amplifier I_{OCP} usually defines a threshold for enabling the over-current protections (OCP), thus, leaving more time for enabling such short circuit protection measures before the entering of the full-bridge output stage in non-safe operative conditions.

For instance, short circuits can be detected in presence of an output current Lout value equal to or smaller than half the value of the maximum current allowed to flow in transistors of the full-bridge class-D amplifier.

It is noted that even if part of the description is focused on full-bridge class-D amplifiers used in audio applications, solutions as described herein can be applied to any full-bridge class-D amplifier where short circuits of the outputs to ground GND or to the supply voltage VCC have to be detected.

Solutions as described herein are related to a circuit for detecting short circuits in full-bridge class-D amplifiers based on the following operations: a checking operation used for verifying the presence of imbalances between measures related to a high-side switch of a branch of the full-bridge, that is, either to the first high-side switch HP or the second high-side switch HM, and measures related to the low-side switch of the other branch of such full-bridge, that is, to the second low-side switch LM or the first low-side switch LP respectively; and a detection operation that detects the presence of a short circuit to ground GND or to the supply voltage VCC (or battery voltage, if different) if the checking operation indicates that an imbalance between such measures is present.

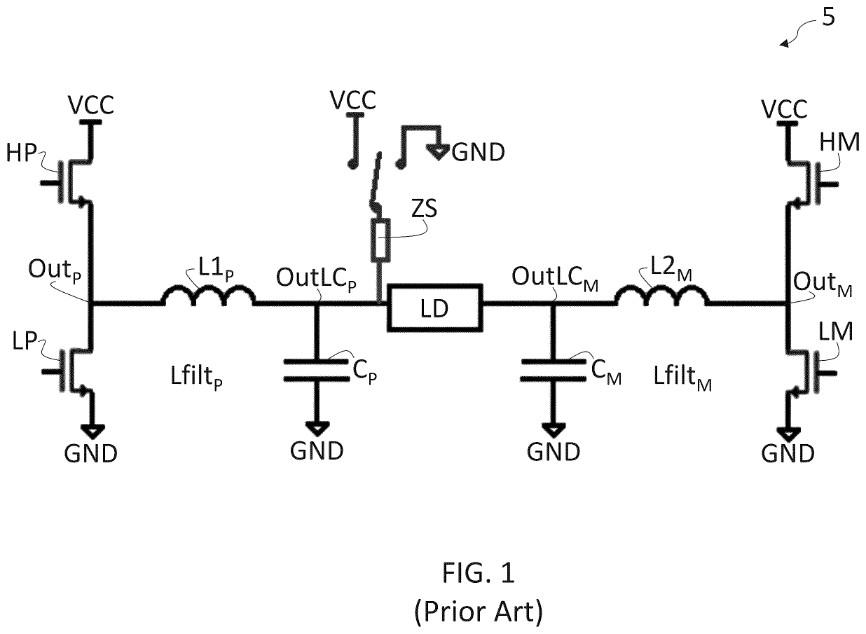

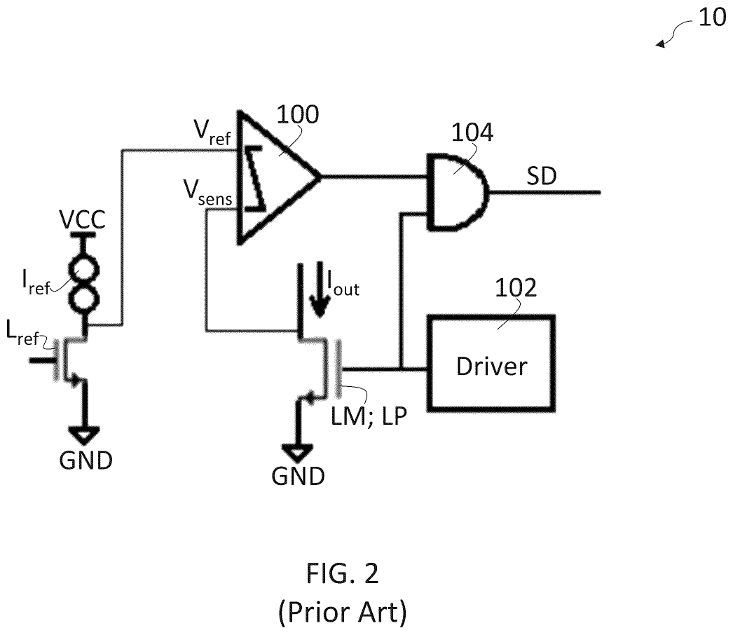

Therefore, solutions as described herein refers to a circuit for detecting electrical short circuits, for instance, short circuit events to ground GND, to the supply voltage VCC, or to the battery voltage (if different from the supply voltage VCC), in a full-bridge class-D amplifier such as the full-bridge class-D amplifier 5 illustrated in FIG. 1.

Therefore, such full-bridge class-D amplifier 5 comprises: a first branch comprising a first high-side switch HP configured to be coupled between a supply voltage VCC and a first output node Out_{P} and a first low-side switch LP configured to be coupled between such first output node Out_{P} and ground GND; and a second branch comprising a second high-side switch HM configured to be coupled between such supply voltage VCC and a second output node Out_{M} and a second low-side switch LM configured to be coupled between such second output node Out_{M} and ground GND.

The circuit according to solutions as described herein comprises: a measuring circuit configured to provide a first measure of a first operating characteristic (for instance, a current, a voltage, or a time measure) of the high-side switch (for instance, HP or HM) comprised in one of the first branch and the second branch of the full-bridge class-D amplifier 5, and a second measure of a second operating characteristic (for instance, again a current, a voltage, or a time measure) of the low-side switch (for instance, LM or LP respectively) comprised in the other of the first branch and the second branch of the full-bridge class-D amplifier 5; a checking circuit configured to receive from the measuring circuit the first measure and the second measure and to provide an imbalance signal indicative of the presence of imbalance between such first measure and such second measure; and a detection circuit configured to receive from the checking circuit such imbalance signal and to detect the presence of an electrical short circuit in response to such imbalance signal indicating the presence of imbalance between such first measure and such second measure.

As previously described, solutions as disclosed herein may be implemented via different approaches such as current based approaches or time-based approaches.

Therefore, the measures related to the high-side switch of a branch of the full-bridge and the measures related to the low-side switch of the other branch of such full-bridge may be measures of current.

The measures related to the high-side switch of a branch of the full-bridge are measures of the current flowing in such high-side switch, and the measures related to the low-side switch of the other branch of such full-bridge are measures of the current flowing in such low-side switch.

Alternatively, the measures related to the high-side switch of a branch of the full-bridge and the measures related to the low-side switch of the other branch of such full-bridge may be measures of time.

In such a case, the measures related to the high-side switch of a branch of the full-bridge are measures of a time delay measured: from a rising edge of a driving signal provided to a driver configured to drive such high-side switch to a corresponding rising edge of an output signal provided by such high-side switch.

Similarly, measures related to the low-side switch of the other branch of such full-bridge are measures of a time delay measured: from a falling edge of a driving signal provided to a driver configured to drive such low-side switch to a corresponding falling edge of an output signal provided by such low-side switch.

Therefore, in view of the above, solutions as described herein may refer to a first measure and a second measure which are current-based measures.

For instance, the first measure may be indicative of a current flowing in the high-side switch HP or HM comprised in one of the first branch and the second branch of the full-bridge class-D amplifier 5; and the second measure may be indicative of a current flowing in the low-side switch LM or LP respectively comprised in the other of the first branch and the second branch of the full-bridge class-D amplifier 5.

Similarly, solutions as described herein may refer to a first measure and a second measure which are time-based measures.

In such a case, the first branch and the second branch of the full-bridge class-D amplifier 5 can be driven via respective drivers 102 configured to receive respective driving signals, for instance, the first input signal D_{INP} or the second input signal D_{INM} described in the following description.

Therefore, for instance, the first measure may be indicative of a time delay (referred in the following description with the reference T_{d_r_P} or T_{d_r_M}): from a rising edge of a driving signal D_{INP} or D_{INM} provided to a driver 102_{HP} or 102_{HM} configured to drive said high-side switch HP or HM comprised in one of the first branch and the second branch of the full-bridge class-D amplifier 5 to a corresponding rising edge of an output signal, for instance, a signal provided via the first output node Out_{P} or via the second output node Out_{M}, provided by said high-side switch HP or HM.

Similarly, for instance, the second measure may be indicative of a time delay (referred in the following description with the reference T_{d_f_P} or T_{d_f_M}): from a falling edge of a driving signal D_{INP} or D_{INM} provided to a driver 102_{LP} or 102_{LM} configured to drive said low-side switch LM or LP comprised in the other of the first branch and the second branch of the full-bridge class-D amplifier 5 to a corresponding falling edge of an output signal, for instance, a signal provided via the first output node Out_{P} or via the second output node Out_{M}, provided by said low-side switch LM or LP.

A first approach comprises detecting short circuit conditions based on current measurements, for example, measurements of the currents provided as output by the output terminals of the full-bridge, that is, by the first output node Out_{P} or the second output node Out_{M}.

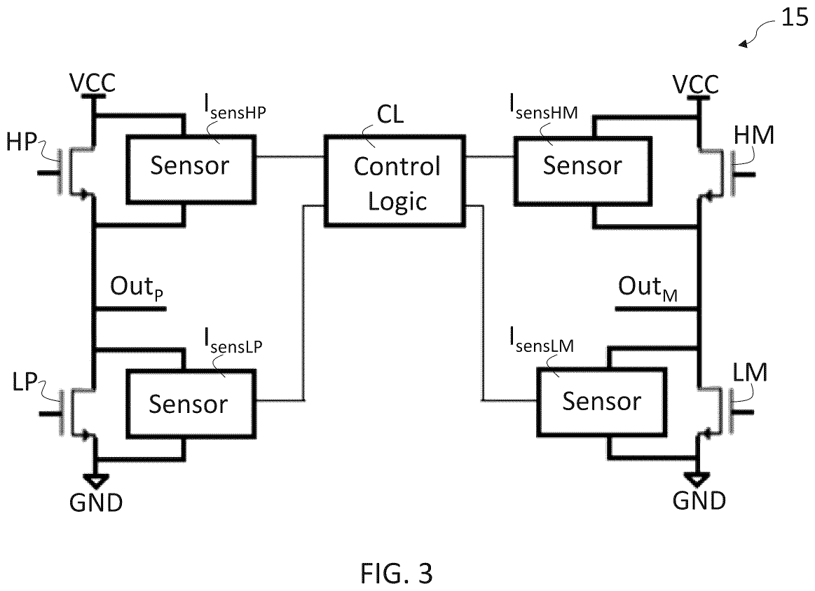

Such first approach is described by referring to the first exemplary circuit 15 illustrated in FIG. 3, configured to detect short circuits, for instance, via a control logic CL, based on current sensing according to embodiments of the present description.

It is noted that, even if in FIG. 3 and in the other figures the transistors comprised in the full-bridge are n-type Metal-Oxide-Semiconductor Field-Effect Transistor (MOSFET), also p-type MOSFET can be considered, and also different types of FETs such as N-DMOS (“double-diffused MOS transistor” of N type), N or P-DMOS kind, GaN FETs (“Gallium Nitride FETs”), or any other available semiconductor technology, can be considered.

In solutions according to such first approach, a current sensor Iₛₑₙₛ is added for each one of the four switches HP, LP, HM, and LM comprised in the full-bridge.

Hence, a first current sensor I_{sensHP} may be configured to sense the current flowing in the first high-side switch HP and to send a signal indicative of such sensed current to a control logic circuit CL. To this purpose, such first current sensor I_{sensHP} may have a first terminal coupled to a current-absorbing (drain) terminal of the first high-side switch HP and a second terminal coupled to a current-supplying (source) terminal of such first high-side switch HP.

Similarly, a second current sensor I_{sensHM} may be configured to sense the current flowing in the second high-side switch HM and to send a signal indicative of such sensed current to the control logic circuit CL. To this purpose, such second current sensor I_{sensHM} may have a first terminal coupled to a current-absorbing (drain) terminal of the second high-side switch HM and a second terminal coupled to a current-supplying (source) terminal of such second high-side switch HM.

A third current sensor I_{sensLP} may be configured to sense the current flowing in the first low-side switch LP and to send a signal indicative of such sensed current to the control logic circuit CL. To this purpose, such third current sensor I_{sensLP} may have a first terminal coupled to a current-absorbing (drain) terminal of the first low-side switch LP and a second terminal coupled to a current-supplying (source) terminal of such first low-side switch LP.

Similarly, a fourth current sensor I_{sensLM} may be configured to sense the current flowing in the second low-side switch LM and to send a signal indicative of such sensed current to the control logic circuit CL. To this purpose, such fourth current sensor I_{sensLM} may have a first terminal coupled to a current-absorbing (drain) terminal of the second low-side switch LM and a second terminal coupled to a current-supplying (source) terminal of such second low-side switch LM.

It is noted that each of such current sensors Iₛₑₙₛ may comprise an analog to digital (fast) converter used to convert the sensed analog currents flowing in respective switches into digital values indicative of such sensed analog currents to be sent to the control logic circuit CL, for instance, via such signals indicative of the sensed currents.

The control logic circuit CL may be configured to: detect the presence of imbalances between a current sensed in a high-side switch of a branch of the full-bridge, that is, a current flowing in either the first high-side switch HP or the second high-side switch HM, and a current sensed in the low-side switch of the other branch of the full-bridge, that is, the current flowing in the second low-side switch LM or in the first low-side switch LP respectively; and determine the presence of a short circuit to the supply voltage VCC (or to the battery voltage, if different) or to ground GND in response to such operation of detecting indicating the presence of an imbalance.

For instance, such imbalance may be detected if an absolute value difference between the current sensed in a high-side switch of a branch of the full-bridge and the current sensed in the low-side switch of the other branch of the full-bridge, obtained either directly or via further conversions, is higher than a threshold.

In fact, the presence of a short circuit to the supply voltage VCC or to ground GND results in adding or subtracting current in one of the outputs of the full-bridge, that is, either to the first output node Out_{P} or the second output node Out_{M}, thus, generating an imbalance between the currents that flow in a high-side switch and those that flow in a low-side switch of the full-bridge, such high-side switch and such low-side switch being simultaneously in a conductive state.

Therefore, in a standard modulation of the full-bridge, the imbalance is considered between a current flowing in the first high-side switch HP, sensed by the first current sensor I_{sensHP}, and the one flowing in the second low-side switch LM, sensed by the fourth current sensor I_{sensLM}, or between a current flowing in the second high-side switch HM, sensed by the second current sensor I_{sensHM}, and the one flowing in the first low-side switch LP, sensed by the third current sensor I_{sensLP}.

It is noted that such threshold may be set between 1/10^{th} and 2/10^{th} of a maximum rated output current that can be provided by a branch of the full-bridge, also considering a current ripple. In fact, the current flowing in each one of the switches during conduction can be obtained as the sum of a current flowing in the load LD and of a ripple current having a triangular wave shape.

Therefore, the checking circuit described above, for instance, implemented via the control logic circuit CL, of a circuit according to solutions as described herein may be configured to check for the presence of imbalance between such first measure and such second measure by: determining an absolute value of a difference between such first measure and such second measure; checking whether such absolute value of the difference is higher than a threshold, for instance, a current, a voltage, or a time threshold; and determining the presence of imbalance if the checking operation indicates that such absolute value of the difference is higher than such threshold.

For instance, as illustrated in FIG. 3, the measuring circuit comprised in circuits according to solutions as described herein may comprise: a first current sensor I_{sensHP} coupled to the first high-side switch HP and configured to sense a current flowing therein; a second current sensor I_{sensHM} coupled to the second high-side switch HM and configured to sense a current flowing therein; a third current sensor I_{sensLP} coupled to the first low-side switch LP and configured to sense a current flowing therein; and a fourth current sensor I_{sensLM} coupled to the second low-side switch LM and configured to sense a current flowing therein.

In such a case, the first measure may be detected either via the first current sensor I_{sensHP} or the second current sensor I_{sensHM} and the second measure may be detected either via the fourth current sensor I_{sensLM} or the third current sensor I_{sensLP}, respectively.

The first current sensor I_{sensHP}, the second current sensor I_{sensHM}, the third current sensor I_{sensLP}, and the fourth current sensor I_{sensLM} may be implemented in different ways.

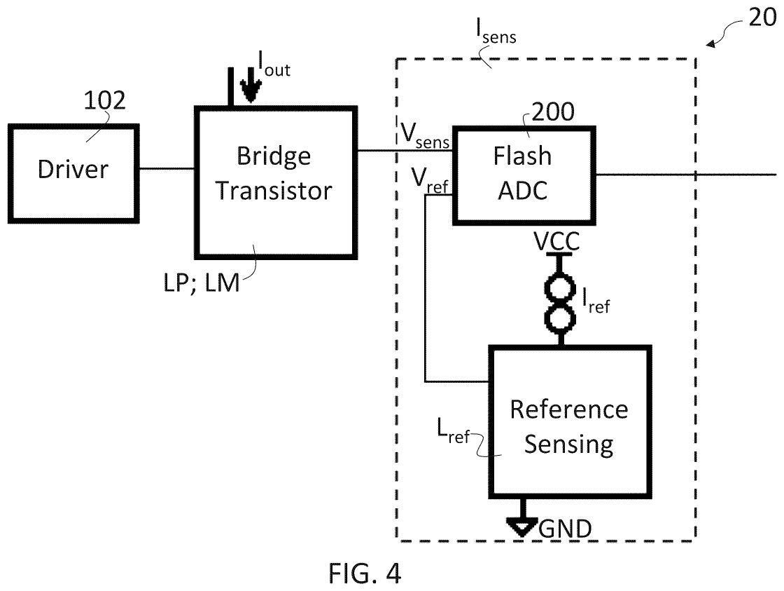

For instance, a first way of implementing the current sensors is illustrated in FIG. 4 and comprises: using a reference voltage V_{ref} as reference for a flash ADC 200, and converting a sensed voltage Vₛₑₙₛ proportional to the current flowing in a respective switch Iₒᵤₜ via such flash ADC 200.

If current sensors according to FIG. 4 are considered, an imbalance can be detected when an absolute value of the difference between the converted value of two different switches that are in a conductive state, that is, for a high-side switch of a branch of the full-bridge and the low-side switch of the other branch of the full-bridge, is above a threshold.

Therefore, FIG. 4 illustrates at reference 20 an exemplary current sensing block Iₛₑₙₛ used in embodiments according to FIG. 3 and configured to perform a conversion operation via an Analog-to-Digital Converter (ADC) 200.

The current sensing block Iₛₑₙₛ, that is, a current sensor according to FIG. 4, may comprise a reference sensing element L_{ref}, for instance, a reference transistor, matched with the respective switch coupled to such current sensing block Iₛₑₙₛ, that is, either the first high-side switch HP, the second high-side switch HM, the first low-side switch LP, or the second low-side switch LM.

For instance, FIG. 4 illustrates a reference sensing element L_{ref} matching either the first low-side switch LP or the second low-side switch LM, since such reference sensing element L_{ref} is referred to ground GND and have injected therein a reference current I_{ref} flowing between its current-absorbing (drain) terminal and its current-supplying (source) terminal.

The reference current I_{ref} corresponds again to a maximum current allowed to flow I_{OCP} in transistors of the full-bridge class-D amplifiers, such a maximum current allowed to flow in such transistors I_{OCP} being obtained according to the equation described above, since such reference sensing element L_{ref} is matched with the respective switch HP, HM, LP or LM.

The current sensing block Iₛₑₙₛ may be configured to receive a sensed voltage Vₛₑₙₛ proportional to the current Iₒᵤₜ provided as output by one of the output terminals of the full-bridge, that is, either to the first output node Out_{P} or the second output node Out_{M}, and flowing in a respective switch, that is, either the first high-side switch HP, the second high-side switch HM, the first low-side switch LP, or the second low-side switch LM, driven via a respective driver 102.

It is underlined again that the exemplary current sensing block Iₛₑₙₛ of FIG. 4 is configured to be coupled to either the first low-side switch LP or the second low-side switch LM. A structure for the first high-side switch HP and the second high-side switch HM may be obtained by using a reference sensing element L_{ref} matched to such high-side switches.

A flash ADC 200 comprised in the current sensing block Iₛₑₙₛ is configured to receive such sensed voltage Vₛₑₙₛ and a reference voltage V_{ref} sensed from the reference sensing element L_{ref}, and to convert such sensed voltage Vₛₑₙₛ into a digital value based on the sensed reference voltage V_{ref} which is used as reference voltage of the flash ADC 200.

The digital value obtained by the flash ADC 200 is provided to the control logic circuit CL, which is configured to detect the presence of imbalances if a digital value received from a current sensor Iₛₑₙₛ coupled to a high-side switch of a branch of the full-bridge and a digital value received from a current sensor Iₛₑₙₛ coupled to the low-side switch of the other branch of the full-bridge differs for more than a given number of ADC levels, for instance, more than 2 ADC levels, from each other.

It is noted that a resolution of a flash ADC 200 used in current sensors Iₛₑₙₛ according to FIG. 4 may also be low, for instance, may comprise 8 levels. In addition, a conversion time of such flash ADC 200 used in current sensors Iₛₑₙₛ according to FIG. 4 may be in the range of about ¼ of the PWM signal period or less.

Therefore, the current sensors I_{sensHP}, I_{sensHM}, I_{sensLP}, and I_{sensLM} according to solutions as described herein may comprise a, preferably flash, Analog-to-Digital Converter (ADC) 200.

Such Analog-to-Digital Converter (ADC) 200 may be configured: to sense a voltage Vₛₑₙₛ proportional to the current flowing in a respective switch, that is, either HP, HM, LP, or LM, coupled to a considered current sensor, that is, either the current sensor I_{sensHP}, I_{sensHM}, I_{sensLP}, or I_{sensLM} respectively; to sense a reference voltage V_{ref} proportional to a maximum acceptable current, for instance, the previously described reference current I_{ref}, flowing in a reference switch, for instance, the previously described reference transistor L_{ref}, matched with said respective switch; and to convert said sensed voltage Vₛₑₙₛ in a digital value based on said sensed reference voltage V_{ref}, such digital value being the first measure or the second measure described above.

It is noted that, since only two switches, that is, HP and LM or HM and LP, of the four switches comprised in the full-bridge can be simultaneously conductive, it is possible to consider only two flash ADC 200, multiplexing their inputs.

Hence, a high-side current sensor may be coupled, for instance, via a multiplexing circuit, either to the first high-side switch HP or the second high-side switch HM in order to detect a current flowing in the high-side of the full-bridge.

Similarly, a low-side current sensor may be coupled, for instance, again via a multiplexing circuit, either to the first low-side switch LP or the second low-side switch LM in order to detect a current flowing in the low-side of the full-bridge.

Therefore, the measuring circuit of circuits according to solutions as described herein may comprise: a high-side current sensor configured to be coupled either to the first high-side switch HP or the second high-side switch HM and to sense a current flowing in the coupled high-side switch HP or HM, and a low-side current sensor configured to be coupled either to the second low-side switch LM or the first low-side switch LP respectively, and to sense a current flowing in the coupled low-side switch LM or LP.

In such a case, the first measure may be detected via the high-side current sensor and the second measure may be detected via the low-side current sensor.

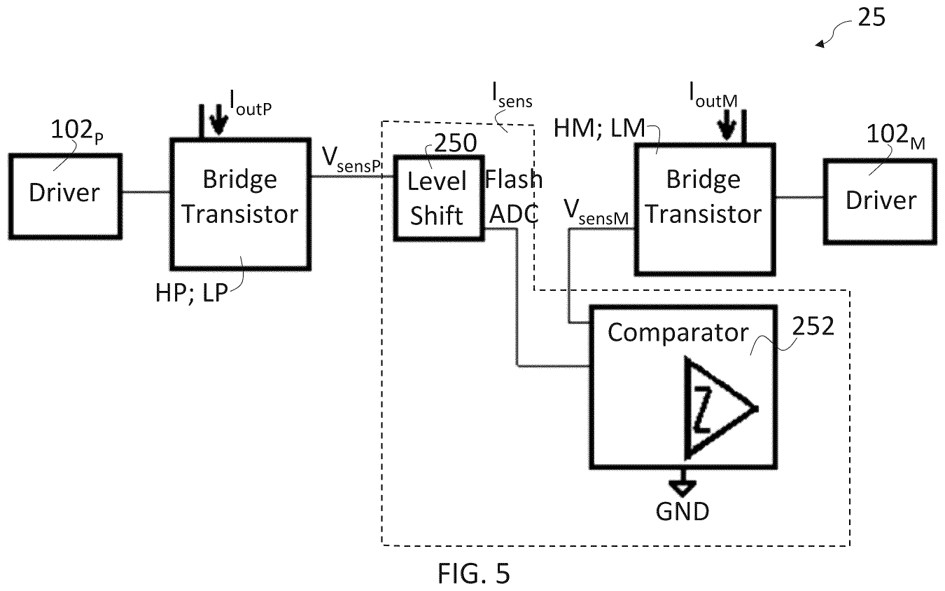

For example, a second way of implementing the current sensors is illustrated in FIG. 5 and comprises: level shifting to a common internal voltage or to ground GND sensed voltages V_{sensP} and V_{sensM} proportional to currents flowing in respective switches I_{outP} and I_{outM} that are in a conductive state, and comparing, obtaining a difference, of the level-shifted sensed voltages V_{sensP} and V_{sensM}.

If current sensors according to FIG. 5 are considered, an imbalance can be detected when the difference between the two level-shifted sensed voltages V_{sensP} and V_{sensM} is above a threshold.

Therefore, FIG. 5 illustrates at reference 25 a further exemplary current sensing block Iₛₑₙₛ used in embodiments according to FIG. 3 and configured to perform a comparison operation via a comparator block 252.

The current sensing block Iₛₑₙₛ, that is, a current sensor according to FIG. 5, may comprise a comparator block 252 coupled to ground GND and a level shifter 250.

The level shifter 250 is configured to: receive a first sensed voltage V_{sensP} proportional to a first current I_{outP} provided as output by the output terminal of a branch of the full-bridge, for instance, the first output node Out_{P}, and flowing in a respective switch of such branch, for instance, either the first high-side switch HP or the first low-side switch LP, driven via a respective first driver 102p; and level shift such received first sensed voltage V_{sensP} to a common internal voltage, for instance, from high-side to low-side if the first sensed voltage V_{sensP} is sensed from the first high-side switch HP and from low-side to high-side if the first sensed voltage V_{sensP} is sensed from the first low-side switch LP.

In solutions according to the present description, the current sensing block Iₛₑₙₛ may comprise an additional level shifter (not shown in FIG. 5 but corresponding to shifter 250), such level shifter being configured to receive a second sensed voltage V_{sensM} proportional to a second current I_{outM} provided as output by the output terminal of the other branch of the full-bridge, for instance, the second output node Out_{M}, and flowing in a respective switch of such other branch, for instance, either the second high-side switch HM or the second low-side switch LM, driven via a respective second driver 102_{M}.

If such additional level shifter is present, the first sensed voltage V_{sensP} and the second sensed voltage V_{sensM} may be level shifted to any common internal voltage or to ground GND.

The comparator block 252, coupled to ground GND, is configured to: receive a first level-shifted voltage provided as output by the level shifter 250 and the second sensed voltage V_{sensM} (or a second level-shifted voltage provided as output by the additional level shifter, if present); and compare such first level-shifted voltage and such second sensed voltage V_{sensM} (or the second level-shifted voltage, if the additional level shifter is present), obtaining an (absolute) voltage difference.

Therefore, as described above, an imbalance can be detected when the (absolute) voltage difference provided by the comparator block 252 is above a threshold.

It is noted that if current sensors according to FIG. 5 are considered, a reference voltage V_{ref} is not requested, but the first high-side switch HP and the second low-side switch LM or the first low-side switch LP and the second high-side switch HM are matched both thermically and versus process spread.

Therefore, the measuring circuit comprised in circuits according to solutions as described herein may comprise a level-shifter 250 configured: to sense one voltage out of a voltage V_{sensP} proportional to the current flowing in the high-side switch HP or HM comprised in one of the first branch and the second branch of the full-bridge class-D amplifier 5 and a voltage V_{sensM} proportional to the current flowing in the low-side switch LM or LP respectively comprised in the other of the first branch and the second branch of the full-bridge class-D amplifier 5; to level-shift such sensed voltage V_{sensP} or V_{sensM} to a voltage level of the other voltage (V_{sensM} or V_{sensP} respectively) out of the voltage V_{sensP} proportional to the current flowing in the high-side switch HP or HM comprised in one of the first branch and the second branch of the full-bridge class-D amplifier 5 and the voltage V_{sensM} proportional to the current flowing in the low-side switch LM or LP respectively comprised in the other of the first branch and the second branch of the full-bridge class-D amplifier 5; to provide such level-shifted sensed voltage as the first measure described above in response to the sensed voltage being the voltage V_{sensP} proportional to the current flowing in the high-side switch HP or HM comprised in one of the first branch and the second branch of the full-bridge class-D amplifier 5, the voltage V_{sensM} proportional to the current flowing in the low-side switch LM or LP comprised in the other of the first branch and the second branch of the full-bridge class-D amplifier 5 being provided as the second measure described above; and to provide the voltage V_{sensP} proportional to the current flowing in the high-side switch HP or HM comprised in one of the first branch and the second branch of the full-bridge class-D amplifier 5 as the first measure described above in response to the sensed voltage being the voltage V_{sensM} proportional to the current flowing in the low-side switch LM or LP comprised in the other of the first branch and the second branch of the full-bridge class-D amplifier 5, such level-shifted sensed voltage being provided as the second measure described above.

Alternatively, the measuring circuit comprised in circuits according to solutions as described herein may comprise: a first level-shifter configured: to sense a voltage V_{sensP} proportional to the current flowing in such high-side switch HP or HM comprised in one of the first branch and the second branch of the full-bridge class-D amplifier 5; to level-shift such sensed voltage V_{sensP} to a voltage level, for instance, to ground GND or to any other voltage level; and to provide such level-shifted sensed voltage as the first measure described above. The solutions may further comprise: a second level-shifter configured: to sense a voltage V_{sensM} proportional to the current flowing in such low-side switch LM or LP respectively comprised in the other of the first branch and the second branch of the full-bridge class-D amplifier 5; to level-shift such sensed voltage V_{sensM} to such voltage level, for instance, to ground GNS or to such any other voltage level; and to provide such level-shifted sensed voltage as the second measure described above.

A second approach comprises again detecting short circuit conditions based on current measurements, for example, measurements of the currents provided as output by the output terminals of the full-bridge I_{outP} and I_{outM}, that is, by either the first output node Out_{P} or the second output node Out_{M}.

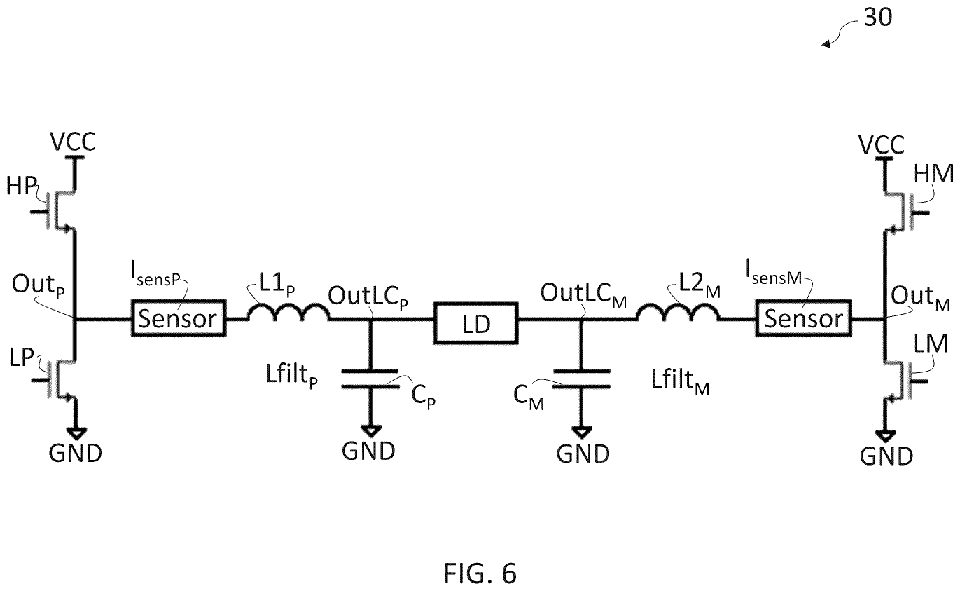

Such second approach is described by referring to the second exemplary circuit 30 illustrated in FIG. 6, configured to detect short circuits based on current sensing.

It is noted that parts, elements, and/or components which have already been described with reference to FIG. 1 are denoted by the same references previously used in such figure. Therefore, the description of such previously described parts, elements, and/or components will not be repeated in the following in order not to overburden the present description.

In solutions according to such second approach, a current sensor Iₛₑₙₛ is placed on the output of each of the two half-bridges of the full-bridge, that is, on each of its branches.

In such a case, a short circuit to the supply voltage VCC or to ground GND can be detected when an imbalance between the currents measured in the two half-bridges is present.

Such imbalance may be determined, for instance, if an absolute value of a difference between a current I_{outP} sensed by a first current sensor I_{sensP} placed on a branch of the full-bridge (for instance, coupled between the first output node Out_{P} and the first inductor L1_{P}, if present) and a current outM sensed by a second current sensor I_{sensM} placed on the other branch of the full-bridge (for instance, coupled between the second output node Out_{M} and the second inductor L2_{M}, if present) is above a threshold. It is noted that such difference may be obtained either via an analog comparator or via a digital conversion, preferably by considering margins due to eventual differential ripple presence.

Otherwise, such imbalance may be determined by: comparing a current I_{outP} sensed by a first current sensor I_{sensP} placed on a branch of the full-bridge with ground GND or with any internal supply, obtaining a first single ended comparison; comparing a current I_{outM} sensed by a second current sensor I_{sensM} placed on the other branch of the full-bridge with ground GND or with the internal supply, obtaining a second single ended comparison; and determining if an absolute value of a difference between the first single ended comparison and the second single ended comparison is higher than a threshold, for instance, via an analog comparator or via a digital conversion, preferably by considering margins due to eventual differential ripple presence. Therefore, the measuring circuit comprised in circuits according to solutions as described herein may comprise: a first branch current sensor, for instance, the first current sensor I_{sensP}, coupled to the first output node Out_{P} (for instance, between the first output node Out_{P} and the first inductor L1_{P} or the load LD) and configured to sense a current I_{outP} flowing therein; and a second branch current sensor, for instance, a second current sensor I_{sensM}, coupled to the second output node Out_{M} (for instance, between the second output node Out_{M} and the second inductor L2_{M} or the load LD) and configured to sense a current I_{outM} flowing therein.

In such a case, the first measure described above may be detected via one current sensor out of the first branch current sensor I_{sensP} and the second branch current sensor I_{sensM} and the second measure described above may be detected via the other current sensor out of the first branch current sensor I_{sensP} and the second branch current sensor I_{sensM}.

In solutions according to the second approach, the current sensors may be implemented via shunt resistors (usually being a MOS parasitic metal resistance), metal sensing, or Hall effects.

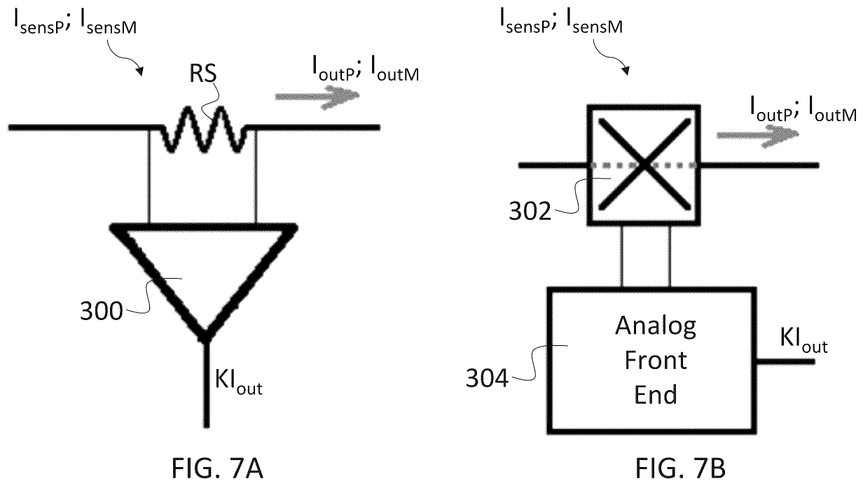

Such implementations are illustrated in FIGS. 7A and 7B, which show exemplary current sensing blocks I_{sensP} and I_{sensM} used in embodiments according to FIG. 6 of the present description.

FIG. 7A illustrates a parasitic or shunt resistor RS into which flows the current provided as output by one of the output terminals of the full-bridge I_{outP} or I_{outM}.

Such current I_{outP} or I_{outM} can be sensed via a comparator 300 having a first input terminal coupled to a first terminal of the parasitic or shunt resistor RS and a second input terminal coupled to a second terminal of the parasitic or shunt resistor RS, such comparator 300 being configured to provide as output a current KIₒᵤₜ proportional to the current I_{outP} or I_{outM} that flows in the parasitic or shunt resistor RS.

It is noted that such comparator 300 advantageously be a fully differential amplifier with a high Common-Mode Rejection Ratio (CMRR).

FIG. 7B illustrates a Hall effect sensor 302 into which flows the current provided as output by one of the output terminals of the full-bridge I_{outP} or I_{outM}.

Such Hall sensor 302 is coupled to an analog front-end (AFE) 304 configured to provide as output a current KIₒᵤₜ proportional to the current I_{outP} or I_{outM} that flows in the Hall sensor 302.

It is noted that such Hall sensor 302 advantageously comprise temperature compensation and offset canceling and amplification features.

Therefore, the first branch current sensor I_{sensP} and the second branch current sensor I_{sensM} described above may be implemented via shunt resistors, preferably by MOS parasitic metal resistance, metal sensing, or Hall effect sensing.

Solutions according to the second approach can be advantageously used in class-D amplifiers without integrated current sensors.

In fact, when a full-bridge class-D amplifier is not equipped with internal (integrated) current sensing elements, current sensors according to such second approach can be applied externally (for instance, at Printed Circuit Board (PCB) level), by placing such current sensors: between the output terminals of the full-bridge (PWM outputs) and the LC filters; or between the LC filters and the load LD.

In such a case, a signal circuitry external to the full-bridge class-D amplifier can be used for performing conditioning operations, analog to digital conversions, and comparison operations.

It is noted that both with the first approach and with the second approach it is possible to detect short circuits before the reaching of the maximum current allowed to flow in the switches of the full-bridge, thus, before that the full-bridge output stage is brought to operate close to non-safe operative conditions, detecting short circuits faster than known solutions.

A further approach comprises detecting short circuit conditions based on time measurements.

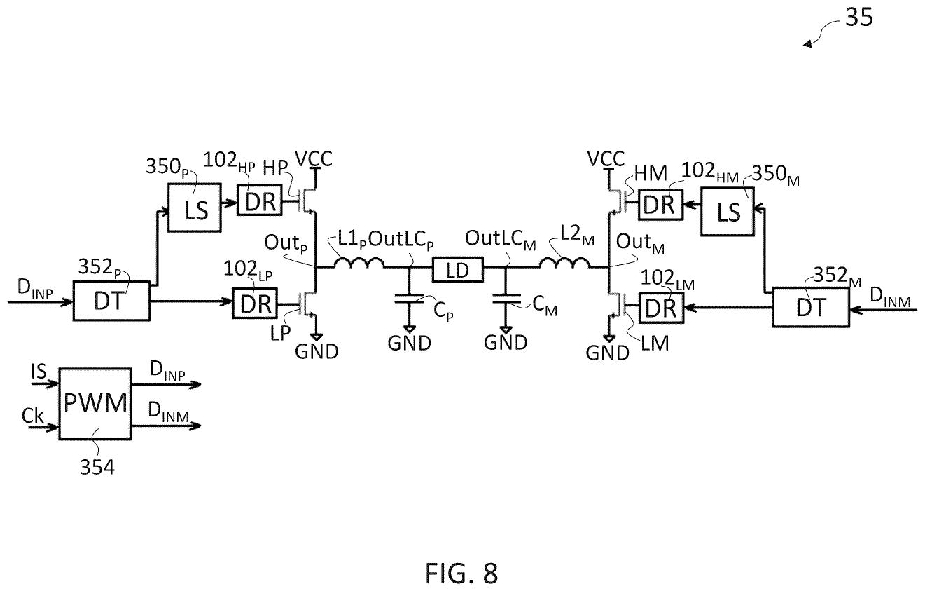

To describe such further approach, an exemplary circuit 35 for managing Pulse-Width Modulation (PWM) signals D_{INP} and D_{INM} used to drive a full-bridge class-D amplifier is illustrated in FIG. 8.

It is noted that parts, elements, and/or components which have already been described with reference to FIG. 1 are denoted by the same references previously used in such figure. Therefore, the description of such previously described parts, elements, and/or components will not be repeated in the following in order not to overburden the present description.

Each of the switches comprised in the full-bridge class-D amplifier may be driven by a respective driver (DR) 102.

Therefore, the first high-side switch HP may be driven by a first high-side driver 102_{HP} coupled to a first low-side to high-side level shifter (LS) 350_{P}, such first high-side driver 102_{HP} being configured to receive a first level-shifted control signal from such first low-side to high-side level shifter 350_{P} and to drive the first high-side switch HP based on such received first level-shifted control signal.

The first low-side to high-side level shifter 350_{P} may be configured to receive a first control signal from a first dead time (DT) conditioning block 352_{P}, to level-shift such received first control signal, obtaining the first level-shifted control signal, and to provide such first level-shifted control signal to the first high-side driver 102_{HP}.

The first dead time conditioning block 352_{P} may be configured to receive a first input signal D_{INP}, for instance, a PWM signal, that is to be provided to either a high-side driver or a low-side driver, and to generate, based on whether such received first input signal D_{INP} is to be provided to the high-side driver or the low-side driver, a first control signal to be provided to the first low-side to high-side level shifter 350_{P} and a second control signal to be provided to a first low-side driver 102_{LP}.

The first low-side switch LP may be driven by such first low-side driver 102_{LP} coupled to the first dead time conditioning block 352_{P}, such first low-side driver 102_{LP} being configured to receive the second control signal from such first dead time conditioning block 352_{P} and to drive the first low-side switch LP based on such received second control signal.

Similarly, the second high-side switch HM may be driven by a second high-side driver 102_{HM} coupled to a second low-side to high-side level shifter 350_{M}, such second high-side driver 102_{HM} being configured to receive a second level-shifted control signal from such second low-side to high-side level shifter 350_{M} and to drive the second high-side switch HM based on such received second level-shifted control signal.

The second low-side to high-side level shifter 350_{M} may be configured to receive a further first control signal from a second dead time conditioning block 352_{M}, to level-shift such received further first control signal, obtaining the second level-shifted control signal, and to provide such second level-shifted control signal to the second high-side driver 102_{HM}.

The second dead time conditioning block 352_{M} may be configured to receive a second input signal D_{INM}, for instance, a PWM signal, that is to be provided to either a high-side driver or a low-side driver, and to generate, based on whether such received second input signal D_{INM} is to be provided to the high-side driver or the low-side driver, a further first control signal to be provided to the second low-side to high-side level shifter 350_{M} and a further second control signal to be provided to a second low-side driver 102_{LM}.

The second low-side switch LM may be driven by such second low-side driver 102_{LM} coupled to the second dead time conditioning block 352_{M}, such second low-side driver 102_{LM} being configured to receive the further second control signal from such second dead time conditioning block 352_{M} and to drive the second low-side switch LM based on such received further second control signal.

The first input signal D_{INP} that is to be provided to either the first high-side driver 102_{HP} or the first low-side driver 102_{LP}, for instance, a PWM signal, and the second input signal D_{INM} that is to be provided to either the second high-side driver 102_{HM} or the second low-side driver 102_{LM}, for instance, again a PWM signal, may be generated by a PWM modulation block 354 based on a reference input signal IS and on a clock Ck.

In view of the above, it is possible to define a PWM cycle as the cycle of a Pulse-Width Modulation (PWM) signal generated for driving the half-bridges comprised in the full-bridge via a driver 102 in order to operate the pair of switches HP and LP or HM and LM comprised therein, such PWM signal being either the first input signal D_{INP} or the second input signal D_{INM}.

Thus, solutions according to such further approach comprise measuring at each PWM cycle current dependent time delays corresponding to time laps between rising edges or falling edges of the input signals D_{INP} and D_{INM} that are to be provided to the drivers 102 coupled to respective switches of the half-bridges comprised in the full-bridge and PWM signals provided as output by the branches (that are, half-bridges) of such full-bridge, that is, PWM signals measurable on the first output node Out_{P} or on the second output node Out_{M}.

Such measured current dependent time delays comprise a first time delay T_{d_r_P}, a second time delay T_{d_f_P}, a third time delay T_{d_r_M}, and a fourth time delay T_{d_f_M}.

The first time delay T_{d_r_P} corresponds to a delay from a rising of the first input signal D_{INP} that is to be provided to the first high-side driver 102_{HP} or to the first low-side driver 102_{LP} to a corresponding rising of a PWM signal provided as output by the first high-side switch HP via the first output node Out_{P}.

The second time delay T_{d_f_p} corresponds to a delay from a falling of the first input signal D_{INP} that is to be provided to the first high-side driver 102_{HP} or to the first low-side driver 102_{LP} to a corresponding falling of the PWM signal provided as output by the first low-side switch LP via the first output node Out_{P}.

The third time delay T_{d_r_M} corresponds to a delay from a rising of the second input signal D_{INM} that is to be provided to the second high-side driver 102_{HM} or to the second low-side driver 102_{LM} to a corresponding rising of the PWM signal provided as output by the second high-side switch HM via the second output node Out_{M}.

The fourth time delay T_{d_f_M} corresponds to a delay from a falling of the second input signal D_{INM} that is to be provided to the second high-side driver 102_{HM} or to the second low-side driver 102_{LM} to a corresponding falling of the PWM signal provided as output by the second low-side switch LM via the second output node Out_{M}.

In addition, solutions according to such further approach comprise detecting a short circuit to the supply voltage VCC or to ground GND when an imbalance between the third time delay T_{d_r_M} and the second time delay T_{d_f_P} or the first time delay T_{d_r_P} and the fourth time delay T_{d_f_M} is present, that is, when an imbalance between time delays related to a high-side switch HP or HM of a branch and time delays related to the low-side switch LM or LP respectively of the other branch is present.

For instance, such imbalance may be detected when an absolute value of a difference between such third time delay T_{d_r_M} and such second time delay T_{d_f_P} or such first time delay T_{d_r_P} and such fourth time delay T_{d_f_M} is above a time threshold.

It is noted that in class “BD” modulation the time delays may be stored in a capacitor by voltage conversion and then elaborated, while in class “AD” modulation (usually referred to as Out of Phase modulation) such time delays can be directly elaborated, for instance, by measuring signal (rising and/or falling) front delays between fronts of the PWM signals provided as output by the first output node Out_{P} and the second output node Out_{M} and by checking if such measured signal front delays exceeds the threshold.

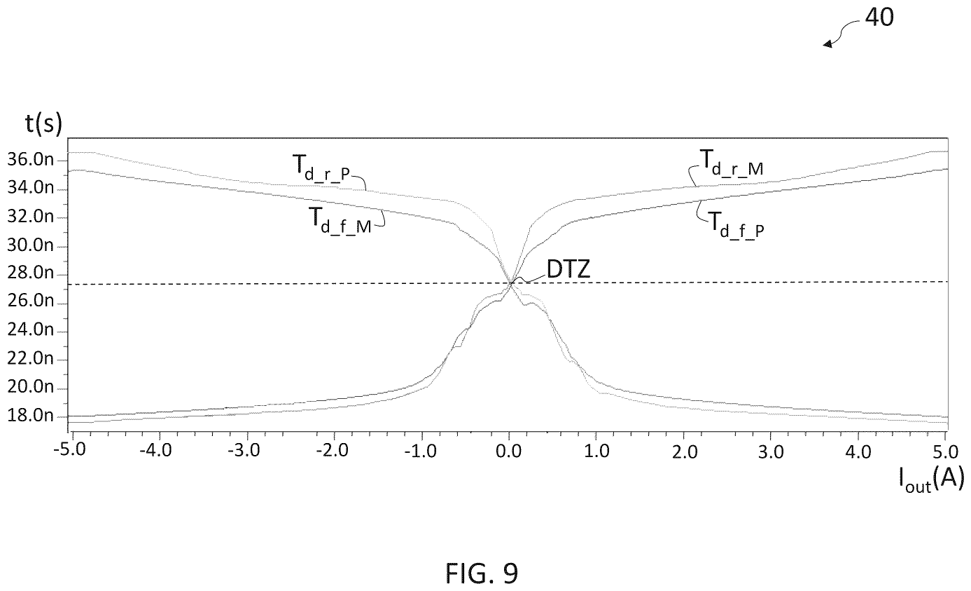

FIG. 9 illustrates behaviors 40 of the previously described time delays T_{d_r_M}, T_{d_f_P}, T_{d_r_P}, and T_{d_f_M} as a function of the output current Iₒᵤₜ provided by the full-bridge class-D amplifier to a load LD coupled therewith, according to embodiments of the present description. It is noted that values and scales reported in FIG. 9 in the time axis t, expressed in seconds(s), and the current axis Iₒᵤₜ, expressed in ampere (A), are only reported therein by way of example, thus, different values and scales may also be considered without affecting the behaviors 40 and the related conclusions described in the following. In fact, such values and scales may change based on the technology that is used to implement the switches of the full-bridge.

In addition to such previously described time delays T_{d_r_M}, T_{d_f_P}, T_{d_r_P}, and T_{d_f_M}, it is possible to define a dead time delay DT that corresponds to a delay: from a rising/falling of the (further) first control signal described above provided by the first (or second) dead time conditioning block 352_{P} (or 352_{M}) to a subsequent falling/rising of the (further) second control signal described above provided by such first (or second) dead time conditioning block 352_{P} (or 352_{M}).

It is noted that such dead time delay DT is considered in order to avoid that a high-side switch, that is, HP or HM, and the low-side switch comprised in the same branch of the full-bridge, that is, LP or LM respectively, are set to a conductive state simultaneously.

It is noted that for values of the output current Iₒᵤₜ close to zero, that is, for low output current Iₒᵤₜ values, the values of the previously described time delays T_{d_r_M}, T_{d_f_P}, T_{d_r_P}, and T_{d_f_M} are close to each other, for instance, close to a value DTZ that depends on the dead time delay DT and on a value of a ripple current (for instance, when the current flowing in the load LD is zero).

It is also noted that with the increasing of the absolute value of the output current Iₒᵤₜ, the values of the previously described time delays T_{d_r_M}, T_{d_f_P}, T_{d_r_P}, and T_{d_f_M} diverge from the value DTZ obtained at zero output load current.

In this regard, the third time delay T_{d_r_M} and the second time delay T_{d_f_P} show a similar behavior, with values that: decrease with respect to the value of the time delay DTZ for negative values of the output current Iₒᵤₜ, that is, when the output current Iₒᵤₜ flows from the first output node Out_{P} to the second output node Out_{M}; and increase with respect to the value of the time delay DTZ for positive values of the output current Iₒᵤₜ, that is, when the output current Iₒᵤₜ flows from the second output node Out_{M} to the first output node Out_{P}.

Similarly, the first time delay T_{d_r_P} and the fourth time delay T_{d_f_M} show a similar behavior, with values that: decrease with respect to the value of the time delay DTZ for positive values of the output current Iₒᵤₜ, and increase with respect to the value of the time delay DTZ for negative values of the output current Iₒᵤₜ.

Therefore, in normal driving conditions, that is, in absence of short circuits, the behavior (and the value) of the third time delay T_{d_r_M} is almost equal to the behavior (and the value) of the second time delay T_{d_f_P} and the behavior (and the value) of the first time delay T_{d_r_P} is almost equal to the behavior (and the value) of the fourth time delay T_{d_f_M}.

It is noted that behaviors of time delays measured on a same branch of the full-bridge, that is, the first time delay T_{d_r_P} and the second time delay T_{d_f_P} or the third time delay Tar M and the fourth time delay T_{d_f_M}, are almost symmetrical, with the output current Iₒᵤₜ changed in sign.

It is noted that the behaviors illustrated in FIG. 9 are present both in Class “BD” modulation, that is, when the fronts of the first input signal D_{INP} and those of the second input signal D_{INM} are not synchronous, and Class “AD” modulation, that is, when the fronts of the first input signal D_{INP} and those of the second input signal D_{INM} are synchronous, for instance, in response to the first input signal D_{INP} being equal to the inversion (for instance, obtained by logic negation) of the second input signal D_{INM}.

In addition, the behaviors illustrated in FIG. 9 may also be present in Zero Switching Loss (ZSL) class-D amplifiers, therefore, solutions as described herein may also be applied to such amplifiers, by treating them as amplifiers having Class “AD” modulation since the time delays are the same in case of exiting and entering currents and decrease or increase in response to the decreasing or the increasing of the output current, in particular in case of low positive output currents and negative currents.

A short circuit condition to the supply voltage VCC or to ground GND is detected when an imbalance is present between: the third time delay T_{d_r_M} and the second time delay T_{d_f_P}, which in normal driving conditions (that is, in absence of short circuits) have an almost equal behavior; or the first time delay T_{d_r_P} and the fourth time delay T_{d_f_M}, which in normal driving conditions have an almost equal behavior.

The imbalance between such third time delay T_{d_r_M} and such second time delay T_{d_f_P} or between such first time delay T_{d_r_P} and such fourth time delay T_{d_f_M} can be detected when an absolute value of a difference between the value of such two considered time delays (which are supposed to be almost equal since their behavior is almost equal) is above a time threshold.

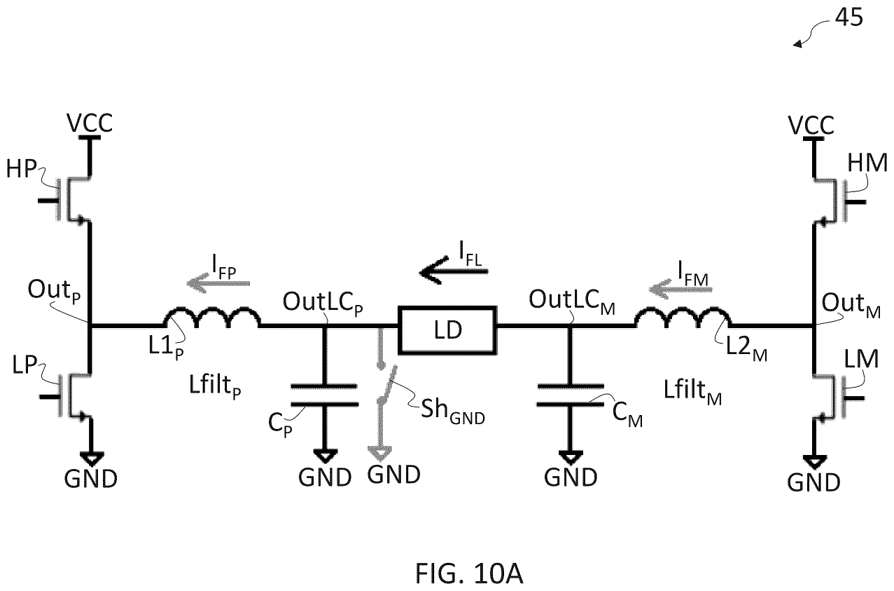

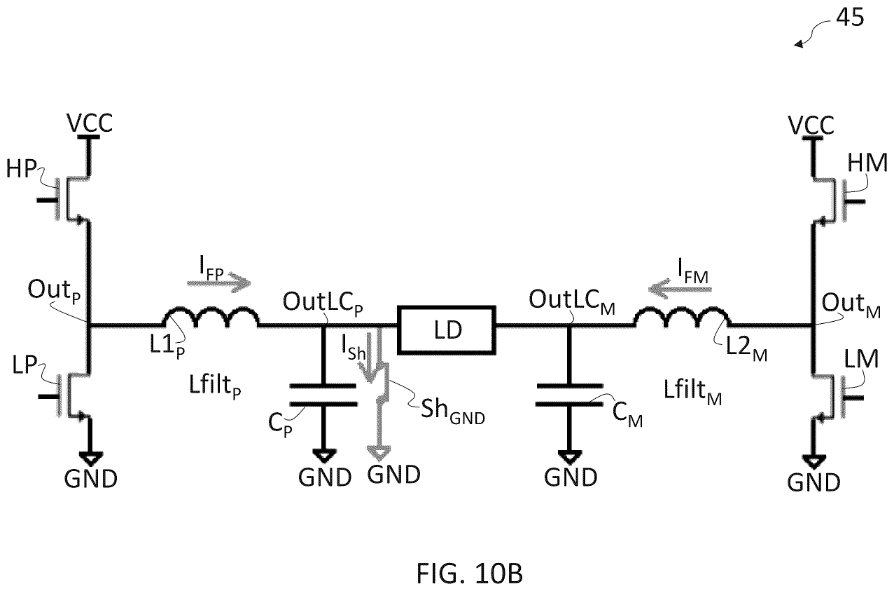

FIGS. 10A and 10B illustrate a full-bridge class-D amplifier 45 having an exemplary short circuit Sh_{GND} to ground GND applied when the outputs Out_{P} and Out_{M} of the amplifier 45 are not saturated (that is, when the first input signal D_{INP} and the second input signal D_{INM} are switching), in embodiments that considers the further approach described above.

The presence of the short circuit Sh_{GND} to ground GND breaks the symmetry on the currents flowing out I_{FM} of the second output node Out_{M} and into I_{FP} the first output node Out_{P}, passing I_{FL} through the load LD, therefore, such currents have different values in response to the presence of such short circuit Sh_{GND}.

For instance, in the exemplary scenario of FIGS. 10A and 10B, the short circuit Sh_{GND} to ground GND is considered on one of the output nodes of the full-bridge, for example, on the first output node Out_{P} where the current I_{FP} is entering, after the LC filtering stage, for example, after the first LC filter Lfilt_{P} and in correspondence of the first output node of the LC filtering stage OutLC_{P}.

In addition, in the exemplary scenario of FIGS. 10A and 10B, it is supposed that: the load LD remains coupled between the first output node of the LC filtering stage OutLC_{P} and the second output node of the LC filtering stage OutLC_{M} after the short circuit Sh_{GND} event, and the current I_{FL} flowing through the load LD was positive before the short circuit Sh_{GND} event, that is, was flowing from the second output node Out_{M} to the first output node Out_{P}.

It is noted that in FIG. 10A, before the short circuit Sh_{GND} event to ground GND, the current I_{FP} flowing into the first output node Out_{P} has a positive value since the output current Iₒᵤₜ (composed of the current I_{FM} provided by the second output node Out_{M} and the current I_{FP} absorbed by the first output node Out_{P}) is flowing from the second output node Out_{M} to the first output node Out_{P}.

Therefore, supposing that: the first input signal D_{INP} is in correspondence of a falling edge, switching from a high logic level to a low logic level, and the second input signal D_{INM} is in correspondence of a rising edge, switching from a low logic level to a high logic level: a measured second time delay T_{d_f_P} and a measured third time delay T_{d_r_M} are (almost) equal and, according to the behaviors illustrated in FIG. 9, have a value above the previously described time delay value DTZ.

In response to the short circuit Sh_{GND} event to ground GND, the current I_{FP} flowing into the first output node Out_{P} starts to decrease and, after a given time, changes its sign (polarity), that is, changes its flow direction (referring to FIG. 10B), by flowing out from the first output node Out_{P} to ground Isₕ.

In response to the changing of the flow direction of the current I_{FP} flowing out from the first output node Out_{P}, the measured second time delay T_{d_f_P} reduces its value from a value higher than the value of the time delay DTZ to a value lower than such time delay value DTZ.

In fact, in response to the short circuit Sh_{GND} event to ground GND, the current I_{FP} is provided as output (and not absorbed) by the first output node Out_{P} (referring to FIG. 10B), therefore, such current I_{FP} has a negative value since the output current out flows out of the first output node Out_{P} to ground ISₕ.

Differently, the current I_{FM} is still provided as output by the second output node Out_{M} and (slowly) increases due to the load LD presence between such second output node Out_{M} and the short circuit Sh_{GND} to ground GND.

Therefore, while the value of the measured second time delay T_{d_f_P} is reduced, the measured third time delay Tar M: maintains its value above the value of the time delay DTZ as the current I_{FM} is still provided as output by the second output node Out_{M}, and (slowly) increases in response to the (slow) increase of such current I_{FM} due to the load LD presence between the second output node Out and the short circuit Sh_{GND} to ground GND.

Therefore, an imbalance between the measured second time delay T_{d_f_P} and the measured third time delay T_{d_r_M} is present.

A similar conclusion may be drawn also by supposing that: the first input signal D_{INP} is in correspondence of a rising edge, switching from a low logic level to a high logic level, and the second input signal D_{INM} is in correspondence of a falling edge, switching from a high logic level to a low logic level.

In such a case, a measured first time delay T_{d_r_P} and a measured fourth time delay T_{d_f_M} are (almost) equal and, according to the behaviors illustrated in FIG. 9, have a value below the value of the time delay DTZ.

In response to the short circuit Sh_{GND} event to ground GND, the current I_{FP} flowing into the first output node Out_{P} starts to decrease and, after a given time, changes its sign (polarity), that is, changes its flow direction (referring to FIG. 10B), by flowing out from the first output node Out_{P} to ground Isₕ.

In response to the changing of the flow direction of the current I_{FP} flowing out from the first output node Out_{P}, the measured first time delay T_{d_r_P} increases its value from a value lower than the value of the time delay DTZ to a value higher than such time delay value DTZ.

In fact, in response to the short circuit Sh_{GND} event to ground GND, the current I_{FP} is provided as output (and not absorbed) by the first output node Out_{P} (referring to FIG. 10B), therefore, such current I_{FP} has a negative value since the output current Iₒᵤₜ flows out of the first output node Out_{P} to ground ISₕ.

Differently, the current I_{FM} is still provided as output by the second output node Out_{M} and (slowly) increases due to the load LD presence between such second output node Out_{M} and the short circuit Sh_{GND} to ground GND.

Therefore, while the value of the measured first time delay Tarp is increased, the measured fourth time delay T_{d_f_M}: maintains its value below the value of the time delay DTZ as the current I_{FM} is still provided as output by the second output node Out_{M}, and (slowly) decreases in response to the (slow) increase of such current I_{FM} due to the load LD presence between the second output node Out_{M} and the short circuit Sh_{GND} to ground GND.

Therefore, also in such case, an imbalance between the measured first time delay T_{d_r_P} and the measured fourth time delay T_{d_f_M} is present.

In both the described cases, such imbalance may be obtained by performing a subtraction operation between: the measured second time delay T_{d_f_P} and the measured third time delay T_{d_r_M}, or the measured first time delay T_{d_r_P} and the measured fourth time delay T_{d_f_M}, and obtaining a time delay difference as the absolute value of the result of the subtraction operation.

Hence, by comparing the obtained time delay difference with a threshold, it is possible to: detect a short circuit presence in response to such time delay difference being higher than (or eventually equal to) the threshold; and detect a short circuit absence in response to such time delay difference being lower than the threshold.

For instance, in solutions using the further approach described herein, a threshold value may be in the order of a quarter of the dead time delay DT (for instance, in the exemplary scenario of FIG. 9, the threshold may assume a value equal to 5 nanoseconds).

It is noted that same conclusions are considered if the short circuit Sh_{GND} to ground GND is present on the second output node Out_{M} where the current I_{FM} is exiting, for example, after the second LC filter Lfilt_{M} and in correspondence of the second output node of the LC filtering stage OutLC_{M}.

In fact, also in such a case an imbalance is present between the measured second time delay T_{d_f_P} and the measured third time delay T_{d_r_M} or the measured first time delay T_{d_r_P} and the measured fourth time delay T_{d_f_M}.

In response to the short circuit Sh_{GND} event to ground GND on the second output node Out_{M}, the current I_{FP} flowing into the first output node Out_{P} starts to (slowly) decrease due to the load LD presence between such first output node Out_{P} and the short circuit Sh_{GND} to ground GND, therefore, (slowly) reducing the measured second time delay T_{d_f_P} and (slowly) increasing the measured first time delay T_{d_r_P}.

In addition, the current I_{FM} provided as output by the second output node Out_{M} increases, therefore, increasing the measured third time delay T_{d_r_M} and decreasing the measured fourth time delay T_{d_f_M}.

It is also noted that the exemplary scenario of FIGS. 10A and 10B considers an Class “AD” modulation, however, the conclusions described above may be considered valid also in solutions using Class “BD” modulation, provided that measured time delays T_{d_f_P}, T_{d_r_M}, T_{d_r_P}, and T_{d_f_M} are stored, for instance, in respective capacitors by voltage conversion, and then elaborated via the previously described subtraction operation and comparing operation. In fact, by storing the measured time delays T_{d_f_P}, T_{d_r_M}, T_{d_r_P}, and T_{d_f_M} it is possible to overcome the fact that pulses in Class “BD” modulation are not synchronous and not overlapping.

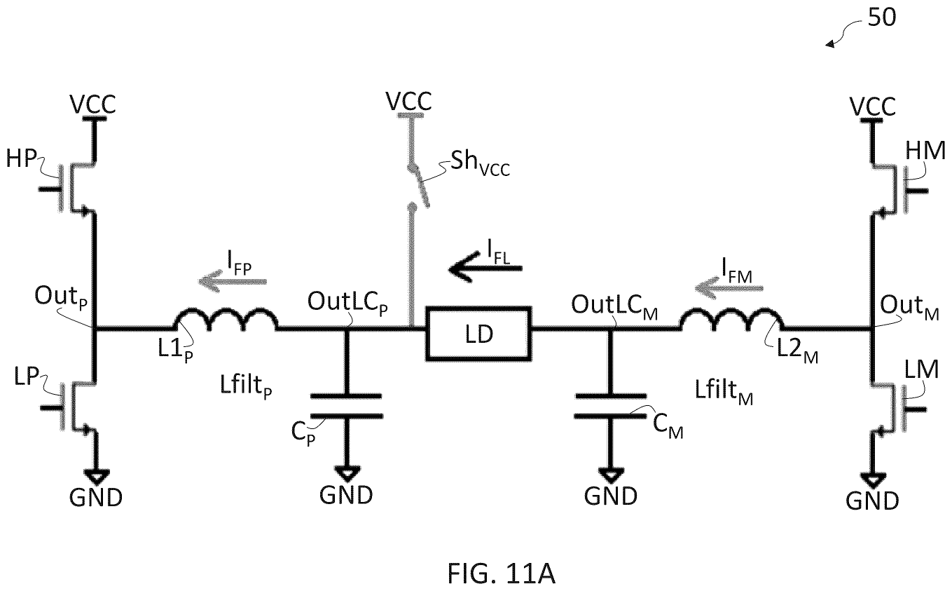

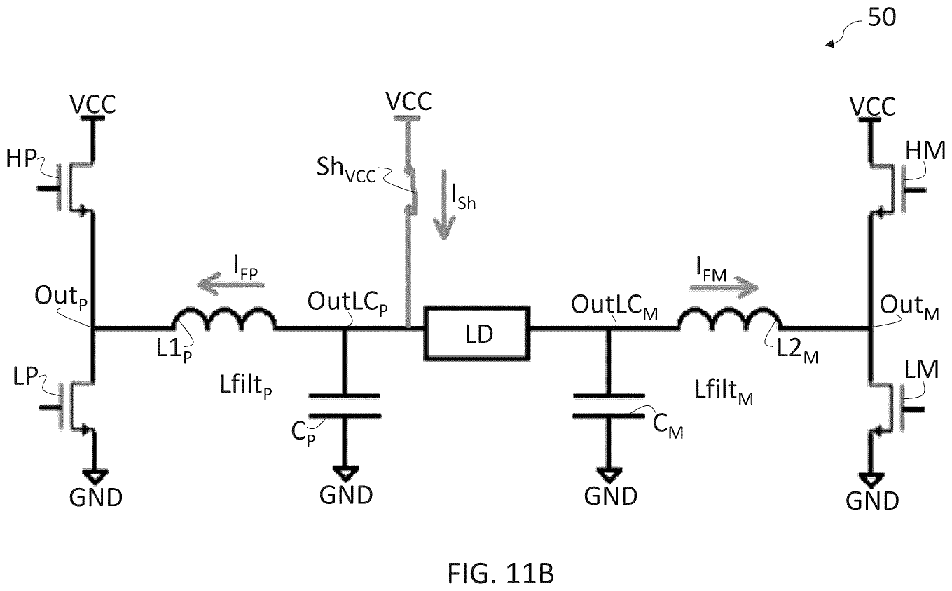

FIGS. 11A and 11B illustrate a full-bridge class-D amplifier 50 having an exemplary short circuit Sh_{VCC} to the supply voltage VCC applied when the outputs Out_{P} and Out_{M} of the amplifier 50 are not saturated (that is, when the first input signal D_{INP} and the second input signal D_{INM} are switching) in embodiments that considers the further approach described above.

The presence of the short circuit Sh_{VCC} to the supply voltage VCC breaks the symmetry on the currents flowing out I_{FM} of the second output node Out_{M} and into I_{FP} the first output node Out_{P}, passing I_{FL} through the load LD, therefore, leading to different values of such currents.

In fact, such presence of the short circuit Sh_{VCC} to the supply voltage VCC leads to: a current injection into one of the two outputs Out_{P} or Out_{M} of the full-bridge, that is, into the output node of the full-bridge currently coupled to ground GND and that receives an entering current, thus, increasing the current flowing in such output node of an amount equal to the injected current Isₕ; and a reduction of a current flowing in the other output of the full-bridge, that is, in the output node of the full-bridge currently coupled to the supply voltage VCC and that provides the output current Iₒᵤₜ, thus, reducing and, after a given time, changing the polarity (sign) of the current exiting from such other output node.

For instance, in the exemplary scenario of FIGS. 11A and 11B, the short circuit Sh_{VCC} to the supply voltage VCC is considered on one of the output nodes of the full-bridge, for example, on the first output node Out_{P} where the current I_{FP} is entering, after the LC filtering stage, for example, after the first LC filter Lfilt_{P} and in correspondence of the first output node of the LC filtering stage OutLC_{P}.

In addition, in the exemplary scenario of FIGS. 11A and 11B, it is supposed that: the load LD remains coupled between the first output node of the LC filtering stage OutLC_{P} and the second output node of the LC filtering stage OutLC_{M} after the short circuit Sh_{VCC} event, and the current I_{FL} flowing through the load LD was positive before the short circuit Sh_{VCC} event, that is, was flowing from the second output node Out_{M} to the first output node Out_{P}.

Therefore, it is noted that, in the exemplary scenario illustrated in such FIGS. 11A and 11B: the first output node Out_{P} is the output node currently coupled to ground GND having an entering current, thus, is the output node where the (positive) current Isₕ generated by the short circuit Sh_{VCC} event is injected, increasing the current I_{FP} flowing therein; and the second output node Out_{M} is the output node currently coupled to the supply voltage VCC and that provides the output current Iₒᵤₜ, thus, is the output node where the current I_{FM} that flows therein is reduced and, after a given time, changes polarity (referring to FIG. 11B).

Therefore, in response to the short circuit Sh_{VCC} event to the supply voltage VCC, the current I_{FP} flowing into the first output node Out_{P} increases, thus, a measured second time delay T_{d_f_P} increases and a measured first time delay T_{d_r_P} decreases.

In response to the short circuit Sh_{VCC} event to the supply voltage VCC, the current I_{FM} provided by the second output node Out_{M} decreases and, after a given time, changes polarity, starting to enter into the second output node Out_{M}.

Therefore, a measured third time delay T_{d_r_M} decreases from a value higher than the value of the time delay DTZ to a value lower than such time delay value DTZ and a measured fourth time delay T_{d_f_M} increases from a value lower than the value of the time delay DTZ to a value higher than such time delay value DTZ.

Therefore, an imbalance between the measured second time delay T_{d_f_P} and the measured third time delay T_{d_r_M} or the measured first time delay T_{d_r_P} and the measured fourth time delay T_{d_f_M} is present.

Such imbalance may be obtained by performing a subtraction operation between: the measured second time delay T_{d_f_P} and the measured third time delay T_{d_r_M}, or the measured first time delay T_{d_r_P} and the measured fourth time delay T_{d_f_M}, and obtaining a time delay difference as the absolute value of the result of the subtraction operation.

Hence, by comparing the obtained time delay difference with a threshold, it is possible to: detect a short circuit presence in response to such time delay difference being higher than (or eventually equal to) the threshold; and detect a short circuit absence in response to such time delay difference being lower than the threshold.

For instance, also in case of short circuits to the supply voltage VCC and in solutions using the further approach described herein, a threshold value may be in the order of a quarter of the dead time delay DT (for instance, in the exemplary scenario of FIG. 9, the threshold may assume a value equal to 5 nanoseconds).

It is noted that same conclusions are considered if the short circuit Sh_{VCC} to the supply voltage VCC is present on the second output node Out_{M} where the current I_{FM} is exiting, for example, after the second LC filter Lfilt_{M} and in correspondence of the second output node of the LC filtering stage OutLC_{M}.

In general, in solutions using both Class “AD” modulation and the further time-based approach described above, it is not requested to measure separately and then compare, for instance, via the described subtraction operation and comparing with the threshold operation, the time delays T_{d_f_P} and Tar Mor T_{d_r_P} and T_{d_f_M}.

In such a case, it may be sufficient to measure a PWM delay between the switching of the PWM signal provided as output by the first high-side switch HP or the first low-side switch LP via the first output node Out_{P} and the switching of the PWM signal provided as output by the second high-side switch HM or the second low-side switch LM via the second output node Out_{M}, or vice versa.

It is noted that temperature mismatches of the switches comprised in the full-bridge or the presence of non-negligible substrate injection may result in systematic current dependent delays of the fronts of the PWM signals, which can be compensated during the measurement of the PWM delay.

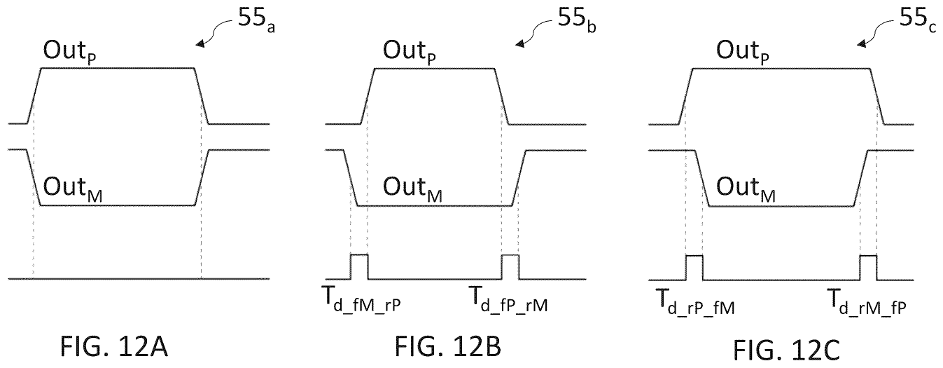

FIGS. 12A, 12B, and 12C illustrate behaviors 55ₐ, 55_{b}, and 55_{c} respectively of fronts of PWM signals provided as output by the full-bridge class-D amplifier according to embodiments of the present description related to the Class “AD” modulation case.

FIG. 12A illustrates the switching (rising and falling) of the PWM signal provided as output by the first high-side switch HP or the first low-side switch LP via the first output node Out_{P} and the corresponding switching (falling and rising) of the PWM signal provided as output by the second high-side switch HM or the second low-side switch LM via the second output node Out during normal driving conditions, that is, in absence of short circuits.

It is noted that in such normal driving conditions, that is, in absence of short circuits and if the full-bridge class-D amplifier is operated via the Class “AD” modulation, the rising (or falling) of the PWM signal provided by the first output node Out_{P} and the corresponding falling (or rising) of the PWM signal provided by the second output node Out_{M} are synchronous.

FIG. 12B illustrates the switching (rising and falling) of the PWM signal provided as output by the first high-side switch HP or the first low-side switch LP via the first output node Out_{P} and the corresponding switching (falling and rising) of the PWM signal provided as output by the second high-side switch HM or the second low-side switch LM via the second output node Out_{M} during a short circuit Sh_{GND} event to ground GND.

It is noted that in conditions where a short circuit Sh_{GND} event to ground GND is present, the rising fronts of the PWM signal provided by the first output node Out_{P} are delayed with respect to the falling fronts of the PWM signal provided by the second output node Out_{M}, and the rising fronts of the PWM signal provided by the second output node Out_{M} are delayed with respect to the falling fronts of the PWM signal provided by the first output node Out_{P}.

In such a case, the absolute value of the difference between the first time delay Tar P and the fourth time delay T_{d_f_M} is equal to a first PWM delay T_{d_fM_rP} measured between the falling edge of the PWM signal provided by the second output node Out_{M} and the rising edge of the PWM signal provided by the first output node Out_{P}.

If such first PWM delay T_{d_fM_rP} is above a threshold, for instance, a threshold in the order of a quarter of the dead time delay DT (for instance, 5 nanoseconds), the presence of a short circuit Sh_{GND} event to ground GND is determined.

Similarly, the absolute value of the difference between the third time delay T_{d_r_M} and the second time delay T_{d_f_P} is equal to a second PWM delay T_{d_fP_rM} measured between the falling edge of the PWM signal provided by the first output node Out_{P} and the rising edge of the PWM signal provided by the second output node Out_{M}.

Therefore, if such second PWM delay T_{d_fP_rM} is above such threshold, for instance, in the order of a quarter of the dead time delay DT, the presence of a short circuit Sh_{GND} event to ground GND is determined.

FIG. 12C illustrates the switching (rising and falling) of the PWM signal provided as output by the first high-side switch HP or the first low-side switch LP via the first output node Out_{P} and the corresponding switching (falling and rising) of the PWM signal provided as output by the second high-side switch HM or the second low-side switch LM via the second output node Out during a short circuit Sh_{VCC} event to the supply voltage VCC.

It is noted that in conditions where a short circuit Sh_{VCC} event to the supply voltage VCC is present, the falling fronts of the PWM signal provided by the first output node Out_{P} are delayed with respect to the rising fronts of the PWM signal provided by the second output node Out_{M}, and the falling fronts of the PWM signal provided by the second output node Out_{M} are delayed with respect to the rising fronts of the PWM signal provided by the first output node Out_{P}.

In such a case, the absolute value of the difference between the first time delay T_{d_r_P} and the fourth time delay T_{d_f_M} is equal to a third PWM delay T_{d_rP_fM} measured between the rising edge of the PWM signal provided by the first output node Out_{P} and the falling edge of the PWM signal provided by the second output node Out_{M}.

If such third PWM delay T_{d_rP_fM} is above such threshold, for instance, a threshold in the order of a quarter of the dead time delay DT, the presence of a short circuit Sh_{VCC} event to the supply voltage VCC is determined.

Similarly, the absolute value of the difference between the third time delay T_{d_r_M} and the second time delay T_{d_f_P} is equal to a fourth PWM delay T_{d_rM_fP} measured between the rising edge of the PWM signal provided by the second output node Out_{M} and the falling edge of the PWM signal provided by the first output node Out_{P}.

Therefore, if such fourth PWM delay T_{d_rM_fP} is above such threshold, for instance, in the order of a quarter of the dead time delay DT, the presence of a short circuit Sh_{VCC} event to the supply voltage VCC is determined.

In general, in solutions using both Class “BD” modulation and the further time-based approach described above, different implementations can be used, provided that the values of the time delays T_{d_f_P} and Tar Mor T_{d_r_P} and T_{d_f_M} are stored before the comparison operation, for instance, performed via the described subtraction operation and comparing with the threshold operation.

Therefore, the measuring circuit comprised in circuits according to solutions as described herein may comprise: a first storing circuit, for instance, a storing circuit having a structure of a storing circuit 604 described in the following, configured to store the first measure described above, and a second storing circuit, for instance, again a storing circuit having a structure of the storing circuit 604 described in the following, configured to store the second measure described above.

In such a case, the checking circuit described above may be configured to receive the first measure and the second measure from such first storing circuit and such second storing circuit, respectively, comprised in the measuring circuit.

In addition, the first storing circuit may be a first capacitor configured to store a voltage indicative of the first measure, and the second storing circuit may be a second capacitor configured to store a voltage indicative of the second measure.

It is noted that, in such a case, such checking circuit may be configured to receive the voltage indicative of the first measure and the voltage indicative of the second measure from such first storing circuit and such second storing circuit, respectively, comprised in the measuring circuit.

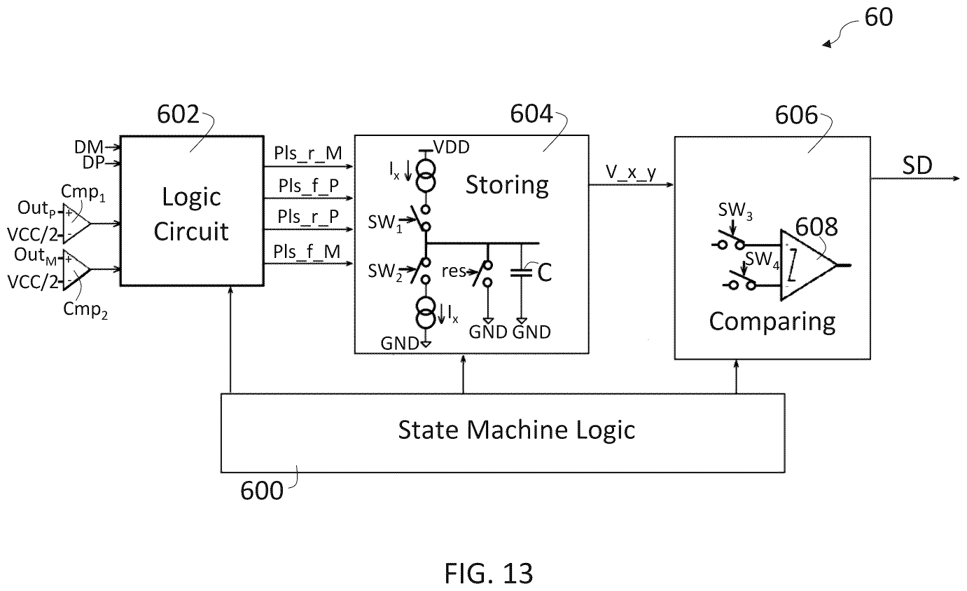

FIG. 13 illustrates a third exemplary circuit 60 for detecting short circuits based on time measurements according to embodiments of solutions using class “BD” modulation. It is noted that, as described above, the implementation illustrated in FIG. 13 is only one of the possible implementations of solutions using both Class “BD” modulation and the further time-based approach described above.

In solutions according to FIG. 13, the PWM signal provided by the first output node Out_{P} is converted into a first logic signal via a first comparator Cmp₁.

Such first comparator Cmp₁ may be configured: to receive such PWM signal provided by the first output node Out_{P} and a voltage reference threshold, for instance, having a value equal to VCC/2, and to provide as output such first logic signal based on a comparison between the received PWM signal provided by the first output node Out_{P} and the voltage reference threshold.

For instance, the first logic signal may have: a high logic level in response to the PWM signal provided by the first output node Out_{P} being higher than the voltage reference threshold; and a low logic level in response to the PWM signal provided by the first output node Out_{P} being lower than the voltage reference threshold.

Similarly, the PWM signal provided by the second output node Out_{M} is converted into a second logic signal via a second comparator Cmp₂.

Such second comparator Cmp₂ may be configured: to receive such PWM signal provided by the second output node Out_{M} and such voltage reference threshold, and to provide as output such second logic signal based on a comparison between the received PWM signal provided by the second output node Out_{M} and the voltage reference threshold.

For instance, the second logic signal may have: a high logic level in response to the PWM signal provided by the second output node Out_{M} being higher than the voltage reference threshold; and a low logic level in response to the PWM signal provided by the second output node Out_{M} being lower than the voltage reference threshold.

The first logic signal, the second logic signal, and further driver control signals (for instance, a driver minimum signal DM and a driver pin signal DP) are provided to a logic circuit 602.

The logic circuit 602 may be configured to generate, based on the received signals, logic pulse signals Pls_r_M, Pls_f_P, Pls_r_P, and Pls_f_M indicative of respective time delays T_{d_r_M}, T_{d_f_P}, T_{d_r_P}, and T_{d_f_M}, for instance, having a width equal to such respective time delays.

The logic pulse signals Pls_r_M, Pls_f_P, Pls_r_P, and Pls_f_M may be provided to a storing circuit 604 that may be configured according to two possible implementations.

In a first implementation, such storing circuit 604 can be configured to convert such logic pulse signals into delay-related voltages V_r_M, V_f_P, V_r_P, and V_f_M by charging respective capacitors C (previously discharged) with a reference current Iₓ for the duration of the respective width of the considered logic pulse signal, and to store such delay-related voltages.

It is noted that such reference current Iₓ is a current having a constant value that may be obtained with any type of known constant current source, for instance, by using a constant current generator as illustrated in the storing circuit 604 in FIG. 13.

For example, an exemplary circuit that can be used for charging and/or discharging the respective capacitors C may comprise: a first switch SW₁ coupled between a certain supply voltage of the capacitor VDD and a node, and configured to close in order to let the reference current Iₓ flow between such supply voltage VDD and the node; a second switch SW₂ coupled between such node and ground GND, and configured to close in order to let the reference current Iₓ flow between such node and ground GND; the respective capacitor C coupled between such node and ground GND, and configured to be charged or discharged with such reference current Iₓ; and a third switch res coupled between such node and ground GND, and configured to close in order to discharge such capacitor C.

It is noted that a respective capacitor C and a corresponding circuit as the one described above may be present for each one of the time delays T_{d_r_M}, T_{d_f_P}, T_{d_r_P}, and T_{d_f_M} that is to be stored.

Alternatively, a first capacitor C and a first exemplary circuit may be present for the high-side switch of a branch of the full-bridge and a second capacitor C and a second exemplary circuit may be present for the low-side switch of the other branch of such full-bridge, such first and second exemplary circuits being coupled, for example, to respective multiplexing circuits in order to receive the logic pulse signals Pls_r_M or Pls_f_P and Pls_r_P or Pls_f_M respectively.

Once such respective capacitors C (for instance, considering a capacitor C for each time delay) store the delay-related voltages V_r_M, V_f_P, V_r_P, and V_f_M, voltage differences between V_r_M and V_f_P or V_r_P and V_f_M may be computed by any known circuit configured to perform voltage comparison operations via voltage comparators, switch-cap, current mirror (after a voltage to current conversion), or the like, for instance, the comparison circuit 606 of FIG. 13.

Such voltage differences between V_r_M and V_f_P or V_r_P and V_f_M are used to detect imbalances and, as a consequence, the presence of a short circuit, for instance, by checking if an absolute value of any one of such voltage differences is above a voltage threshold.

For instance, an operation of detecting imbalances may comprise comparing an absolute value of one of such voltage differences between V_r_M and V_f_P or V_r_P and V_f_M with a voltage threshold, and indicating the presence of a short circuit if the absolute value of the considered voltage difference V_r_M−V_f_P or V_r_P−V_f_M is above the voltage threshold or the absence of a short circuit if such absolute value of the considered voltage difference is below the voltage threshold.

It is noted that such second delay-related voltage V_f_P is equal to the third delay-related voltage V_r_M in normal driving conditions, that is, in absence of short circuits.

It is also noted that such fourth delay-related voltage V_f_M is equal to the first delay-related voltage V_r_P in normal driving conditions.

In a second implementation, a capacitor C is pre-charged at a given voltage, for instance, equal to half the supply voltage of the capacitor VDD/2. The reference current Iₓ can be used to charge such capacitor C by considering the logic pulse Pls_r_M, and then to discharge such capacitor C with such reference current Iₓ by considering the logic pulse Pls_f_P, obtaining a first capacitor voltage equal to VDD/2+V_r_M−V_f_P.

The same can be done with a second capacitor, charged by considering the logic pulse Pls_f_M, and then discharged by considering the logic pulse Pls_r_P, obtaining a second capacitor voltage equal to VDD/2+V_f_M−V_r_P.

The first capacitor voltage and the second capacitor voltage may be compared with at least one voltage threshold, for instance: with a high voltage threshold VTP equal to half the supply voltage VCC plus a given margin VX, that is,

$$V T P = \frac{V C C}{2} + V X ,$$

and with a low voltage threshold VTN equal to half the voltage supply VCC minus the given margin VX, that is,

$$V T N = \frac{V C C}{2} - V X .$$

For instance, such comparison operation may be performed via a comparator 608 configured to receive: at a first input terminal, via a fourth switch SW₃, the first capacitor voltage or the second capacitor voltage; and at a second input terminal, via a fifth switch SW₄, the voltage threshold, for instance, either the voltage threshold plus the given margin or the voltage threshold minus the given margin; and to compare the received inputs, providing as output a short circuit detection signal SD.

The short circuit detection signal SD indicates the presence of a short circuit if: the received first capacitor voltage or second capacitor voltage is above the high voltage threshold VTP, that is, is above the voltage threshold plus the given margin, or the received first capacitor voltage or second capacitor voltage is below the low voltage threshold VTN, that is, is below the voltage threshold minus the given margin.

Otherwise, the short circuit detection signal SD indicates the absence of a short circuit.

It is noted that the logic circuit 602, the storing circuit 604, and the comparison circuit 606 may be controlled via a state machine logic 600.

Hence, for instance, the operation of determining the absolute value of the difference between the first measure and the second measure described above may comprise: pre-charging a capacitor C to a reference voltage, preferably having a value equal to half the supply voltage VCC; charging such capacitor C with a first voltage, such first voltage being indicative of the first measure; discharging such capacitor C with a second voltage, such second voltage being indicative of the second measure, obtaining a capacitor voltage; and providing a first capacitor voltage equal to such capacitor voltage plus a margin and a second capacitor voltage equal to such capacitor voltage minus the margin as the absolute value of the difference between such first measure and such second measure.

In such a case, the operation of checking whether such absolute value of the difference is higher than a threshold described above may comprise checking, for instance, via respective comparators 608, whether: such first capacitor voltage is lower than such voltage reference, that is, whether such capacitor voltage is lower than the voltage reference minus the margin, or such second capacitor voltage is higher than such voltage reference, that is, whether such capacitor voltage is higher than the voltage reference plus the margin.

In general, also solutions using both class “AD” modulation and the further time-based approach described above may be implemented via different circuits.

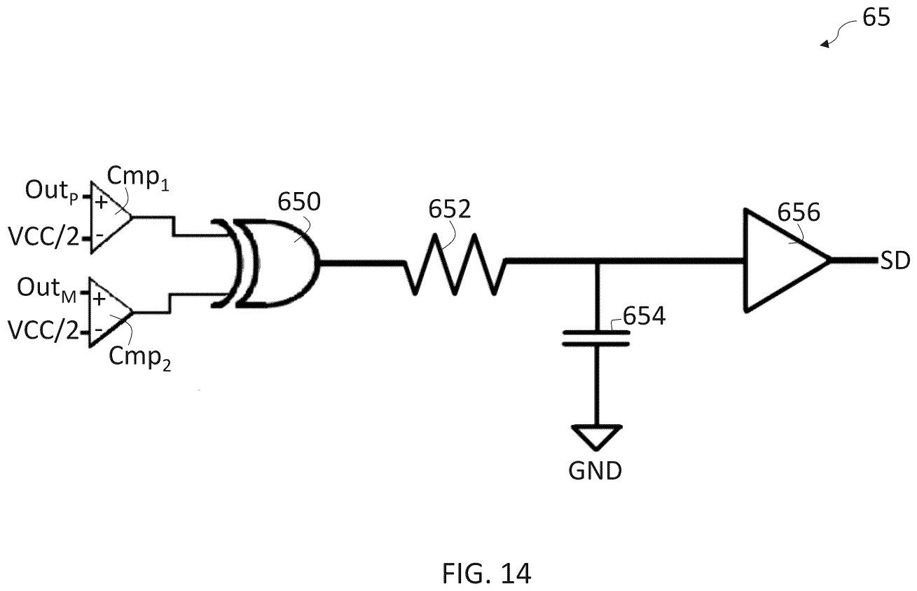

FIG. 14 illustrates a further exemplary circuit 60 for detecting short circuits based on time measurements in class “AD” modulation conditions according to embodiments of the present description. It is noted that, as described above, the implementation illustrated in FIG. 14 is only one of the possible implementations of solutions using both class “AD” modulation and the further time-based approach described above.

In fact, as previously described for class “AD” modulation in case of a short circuit to ground GND, the first PWM delay T_{d_fM_rP}, the second PWM delay T_{d_fP_rM}, the third PWM delay T_{d_rP_fM}, and the fourth PWM delay T_{d_rM_fP} may be measured via direct logic elaboration of the PWM signal provided by the first output node Out_{P} and the PWM signal provided by the second output node Out_{M}. A same conclusion is also valid in case of short circuits to the supply voltage VCC.

A first implementation (not illustrated in FIG. 14) may be obtained by a circuit configured to evaluate the width of such PWM delays, by converting them into voltages and by comparing the obtained voltages with a reference voltage generated by a known time pulse.

FIG. 14 illustrates a simpler implementation that can be used if a high accuracy is not required.

In solutions according to FIG. 14, the PWM signal provided by the first output node Out_{P} is converted into a first logic signal via a first comparator Cmp₁.

Such first comparator Cmp₁ may be configured: to receive such PWM signal provided by the first output node Out_{P} and a voltage reference threshold, for instance, having a value equal to VCC/2, and to provide as output such first logic signal based on a comparison between the received PWM signal provided by the first output node Out_{P} and the voltage reference threshold, for instance, by providing as output a high logic level when such PWM signal provided by the first output node Out_{P} is higher than the voltage reference threshold and a low logic level otherwise.

Similarly, the PWM signal provided by the second output node Out is converted into a second logic signal via a second comparator Cmp₂.

Such second comparator Cmp₂ may be configured: to receive such PWM signal provided by the second output node Out_{M} and such voltage reference threshold, and to provide as output such second logic signal based on a comparison between the received PWM signal provided by the second output node Out_{M} and the voltage reference threshold, for instance, by providing as output a high logic level when such PWM signal provided by the second output node Out_{M} is higher than such voltage reference threshold and a low logic level otherwise.

The first logic signal and the second logic signal are provided to a logic XOR block 650 configured to perform a logic XOR operation on such first logic signal and such second logic signal.

It is noted that, during the first PWM delay T_{d_fM_rP}, the second PWM delay T_{d_fP_rM}, the third PWM delay T_{d_rP_fM}, and the fourth PWM delay T_{d_rM_fP}, the XOR of the first logic signal and the second logic signal provided as output by the logic XOR block 650 may assume a low logic level (thus, indicating the absence of a short circuit to the supply voltage VCC or to ground), otherwise, such result of the XOR operation may assume a high logic level (thus, indicating the presence of a short circuit).

The XOR of the first logic signal and the second logic signal provided as output by the logic XOR block 650 may be filtered via an RC circuit comprising a resistor 652 and a capacitor 654 in order to determine whether such signal provided as output by the logic XOR block 650 has a duration of its high logic level that is above a certain threshold.

The signal provided as output by the filtering stage RC is provided as input to an inverter 656 (for instance, a CMOS buffer).

Such inverter 656 is configured to provide as output a short circuit detection signal SD indicating either the presence of a short circuit if the signal provided as output by the filtering stage indicates that such duration is above such certain threshold or the absence of a short circuit if such signal provided as output by the filtering stage indicates that the duration is below the certain threshold.

Therefore, both in embodiments according to FIG. 14 or FIGS. 12A, 12B, and 12C, that is, in embodiments that use class “AD” modulation, and in embodiments according to FIG. 13 related to the use of class “BD” modulation, the checking operation used for verifying the presence of current imbalances between measures related to a high-side switch of a branch of the full-bridge and measures related to the low-side switch of the other branch of such full-bridge may be done by considering the delay of the rising of the voltage output provided by the first node Out_{P} versus the falling of the voltage output provided by the second node Out_{M}, or vice versa, Out_{P} falling versus Out_{M} rising as described above.

Output nodes Out_{P} and Out_{M} do not usually output logic signals (both for voltage rail belonging and for non-regular fronts), thus their outputs are to be converted into logic signals, for instance, by using voltage comparators Cmp₁ and Cmp₂, having a threshold equal to, for instance, VCC/2 as described above.

For instance, in embodiments related to class “BD” modulation and according to the exemplary implementation of FIG. 13, the presence of imbalances may be checked by comparing the output signals provided by the output nodes Out_{P} and Out_{M} of the full-bridge class-D amplifier with a voltage reference threshold, for instance, having a value equal to VCC/2, obtaining two logic signals representing the timing behavior of such output signals provided by the nodes Out_{P} and Out_{M}.

These two logic signals are provided as output by the comparators Cmp₁ and Cmp₂ and are sent to the logic circuit 602 to generate the logic pulse signals Pls_r_M, Pls_f_P, Pls_r_P, and Pls_f_M indicative of respective time delays T_{d_r_M}, T_{d_f_P}, T_{d_r_P}, and T_{d_f_M}, for instance, having a width equal to such respective time delays.

Such logic pulse signals, in order to be compared asynchronously, are to be converted into voltage levels by charging and then discharging a capacitor C according to the first and the second implementations described above.

For instance, in embodiments related to class “AD” modulation and according to the exemplary implementation of FIG. 14, the presence of imbalances may be checked by: directly coupling the outputs of the comparators Cmp₁ and Cmp₂ to the logic XOR block 650 described above; and determining the presence of an imbalance if the resulting logic output provided by the logic XOR block 650 has a duration that is above a certain value. To verify whether such duration is above the certain value, it is possible to use an RC circuit 652 and 654 followed by an inverter 656.

Therefore, in circuits according to solutions as described herein, a first measure and a second measure may be time-based measurements obtained from a voltage-based measurement, preferably performed via fast comparators Cmp₁ and Cmp₂.

It is noted that such comparators Cmp₁ and Cmp₂ are to be designed to have a time response to the rising fronts TC_rise and a time response to the falling fronts TC_fall such that: the value of the time response to the rising fronts TC_rise and the value of the time response to the falling fronts TC_fall, and the difference between such value of the time response to the rising fronts TC_rise and such value of the time response to the falling fronts TC_fall, are comprised within the pulse width resolution Tres of the output signals Out_{P} or Out_{M} (such pulse width resolution Tres being usually around 1 nanosecond).

In addition, such comparators Cmp₁ and Cmp₂ are to be well matched, for instance, having a time response difference smaller than such pulse width resolution Tres.

Instead, in embodiments according to FIG. 14, the checking circuit may be configured to check for the presence of imbalance between such first measure and such second measure by verifying, preferably via a logic XOR operator 650 and an RC filtering stage comprising a resistor 652 and a capacitor 654 and coupled to an inverter 656, whether one logic signal among: a first logic signal indicative of a time behavior of the output signal provided, via the node Out_{P} or Out_{M}, by the high-side switch HP or HM comprised in one of the first branch and the second branch of the full-bridge class-D amplifier 5, preferably obtained via the first comparator Cmp₁ having a reference voltage threshold equal to half the supply voltage VCC, such first logic signal being indicative of one of the first measure and the second measure, and a second logic signal indicative of a time behavior of the output signal provided, via the node Out_{M} or Out_{P} respectively, by the low-side switch LM or LP, comprised in the other of the first branch and the second branch of the full-bridge class-D amplifier 5, preferably obtained via the second comparator Cmp₂ having a reference voltage threshold equal to half the supply voltage VCC, such second logic signal being indicative of the other of the first measure and the second measure, assumes a certain logic level, for instance, a high logic level, for a duration higher than a duration threshold; and by determining the presence of imbalance if the verifying operation indicates that either the first logic signal or the second logic signal assumes such certain logic level, for instance, a high logic level, for a duration higher than such duration threshold.

It is noted that in case of non-negligible asymmetries in the dynamic behavior of a low-side switch and a high-side switch of the full-bridge, such asymmetries resulting in a rising edge of a PWM signal provided as output by the full-bridge being delayed with respect to a falling edge of the other PWM signal provided as output by the full-bridge during normal driving conditions (that is, in absence of short circuits), it is possible to detect the short circuit by considering the happening of two consecutive pulses of the output buffer, that is, the happening of two consecutive short circuit presence indications of the short circuit detection signal SD.

Therefore, it is noted that also by using the described further approach (or the voltage-based approach described in FIGS. 13 and 14) it is possible to detect short circuits before the reaching of the maximum current allowed to flow in the switches of the full-bridge, thus, before that the full-bridge output stage is brought to operate close to non-safe operative conditions, detecting short circuits faster than known solutions.

In view of the above, it is noted that solutions as described herein facilitate the detection of short circuit conditions using asymmetries of the dynamic variables of full-bridge class-D amplifiers, that is, current, voltage, and time delays, caused by the presence of short circuits.

Solutions as described herein facilitate obtaining a circuit for detecting electrical short circuits, for instance, short circuit events to ground Sh_{GND}, to the supply voltage Sh_{VCC}, or to the battery voltage (if different from the supply voltage VCC), in a full-bridge class-D amplifier such as the full-bridge class-D amplifier 5 illustrated in FIG. 1, such full-bridge class-D amplifier 5 comprising: a first branch comprising a first high-side switch HP configured to be coupled between a supply voltage VCC and a first output node Out_{P} and a first low-side switch LP configured to be coupled between such first output node Out_{P} and ground GND; and a second branch comprising a second high-side switch HM configured to be coupled between such supply voltage VCC and a second output node Out_{M} and a second low-side switch LM configured to be coupled between such second output node Out_{M} and ground GND.

The circuit according to solutions as described herein comprises: a measuring circuit (for instance, the current sensors Iₛₑₙₛ, the logic circuit 602 and the storing circuit 604, or the components 650-654 of FIG. 14) configured to provide: a first measure of a first operating characteristic (for instance, a current, a voltage, or a time measure) of the high-side switch (for instance, HP or HM) comprised in one of the first branch and the second branch of the full-bridge class-D amplifier 5; and a second measure of a second operating characteristic (for instance, again a current, a voltage, or a time measure) of the low-side switch (for instance, LM or LP respectively) comprised in the other of the first branch and the second branch of the full-bridge class-D amplifier 5; a checking circuit (for instance, the control logic circuit CL, the comparison circuit 606, or the inverter 656) configured to receive from the measuring circuit the first measure and the second measure and to provide an imbalance signal, for instance, the short detection signal SD, indicative of the presence of imbalance between such first measure and such second measure; and a detection circuit configured to receive from the checking circuit such imbalance signal SD and to detect the presence of an electrical short circuit in response to such imbalance signal SD indicating the presence of imbalance between such first measure and such second measure.

In addition, the checking circuit of a circuit according to solutions as described herein may be configured to check for the presence of imbalance between such first measure and such second measure by: determining an absolute value of a difference between such first measure and such second measure; checking whether such absolute value of the difference is higher than a threshold, for instance, a current, a voltage, or a time threshold; and determining the presence of imbalance if the checking operation indicates that such absolute value of the difference is higher than such threshold.

Thus, solutions as described herein facilitate providing reliable short circuit detection and protection features even in presence of supply voltages having high values, for instance, supply voltages above 14.4V, hence, improving safety and preventing dangerous or faulty conditions due to the presence of such short circuits, improving the robustness of full-bridge class-D amplifiers to short circuits to the supply voltage VCC, to ground GND, or to a battery voltage (if different from the supply voltage VCC).

In addition, solutions as described herein facilitate discriminating in a (even very) short time, for instance, in few periods of a Pulse-Width Modulation (PWM) signal used to drive a full-bridge class-D amplifier, the presence of a short circuit to ground GND or to the supply voltage VCC with respect to the normal driving conditions.

The detection of the presence of a short circuit described in the above is performed independently from the value of an output current Iₒᵤₜ provided by the full-bridge class-D amplifier to a load LD coupled therewith, that is, independently from the value of the output current Iₒᵤₜ with respect to a maximum current allowed to flow in the switches of the full-bridge.

In this regard, the short circuit can be detected also in presence of output current Iₒᵤₜ values that are lower than the maximum current allowed to flow in transistors of the full-bridge class-D amplifier that is usually considered as a threshold for enabling the over-current protections (OCP).

Therefore, in solutions according to the present description, more time is available for enabling the short circuit protection measures (that is, the OCP) before that the full-bridge output stage enters in non-safe operative conditions.

In fact, in every one of the approaches described above, it is possible to detect short circuits before the reaching of the maximum current allowed to flow in the switches of the full-bridge, thus, before that the full-bridge output stage is brought to operate close to non-safe operative conditions, hence, the detection of short circuits is faster.

It is noted that solutions as described herein also refers to a method of detecting electrical short circuits, for instance, short circuit events to ground Sh_{GND}, to the supply voltage Sh_{VCC}, or to the battery voltage (if different from the supply voltage VCC), in a full-bridge class-D amplifier such as the full-bridge class-D amplifier 5 illustrated in FIG. 1.

The full-bridge class-D amplifier 5 comprises: a first branch comprising a first high-side switch HP configured to be coupled between a supply voltage VCC and a first output node Out_{P} and a first low-side switch LP configured to be coupled between such first output node Out_{P} and ground GND; and a second branch comprising a second high-side switch HM configured to be coupled between such supply voltage VCC and a second output node Out_{M} and a second low-side switch LM configured to be coupled between such second output node Out_{M} and ground GND.

The method according to solutions as described herein comprises: providing, via a measuring circuit (for instance, the current sensors Iₛₑₙₛ, the logic circuit 602 and the storing circuit 604, or the components 650-654 of FIG. 14): a first measure of a first operating characteristic (for instance, a current, a voltage, or a time measure) of the high-side switch HP or HM comprised in one of the first branch and the second branch of the full-bridge class-D amplifier 5; and a second measure of a second operating characteristic (for instance, again a current, a voltage, or a time measure) of the low-side switch LM or LP comprised in the other of the first branch and the second branch of the full-bridge class-D amplifier 5; receiving, at a checking circuit (for instance, the control logic circuit CL, the comparison circuit 606, or the inverter 656), the first measure and the second measure from the measuring circuit; providing, via the checking circuit, an imbalance signal indicative of the presence of imbalance between such first measure and such second measure, for instance, the short detection signal SD described above; receiving, at a detection circuit, such imbalance signal SD from the checking circuit; and detecting, via the detection circuit, the presence of an electrical short circuit in response to such imbalance signal SD being indicative of the presence of imbalance between such first measure and such second measure.

In addition, the method according to solutions as described herein may comprise checking, via the checking circuit, for the presence of imbalance between the first measure and the second measure by: determining an absolute value of a difference between the first measure and the second measure; checking whether the absolute value of the difference is higher than a threshold, for instance, a current, a voltage, or a time threshold; and determining the presence of imbalance if the checking operation indicates that the absolute value of the difference is higher than such threshold.

It is also noted that the method according to the present description may further comprise any other step to implement the operations performed by the circuit according to the description above.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A circuit for detecting electrical short circuits in a full-bridge class-D amplifier, wherein the full-bridge class-D amplifier includes: a first branch comprising a first high-side switch configured to be coupled between a supply voltage and a first output node and a first low-side switch configured to be coupled between said first output node and ground; and a second branch comprising a second high-side switch configured to be coupled between said supply voltage and a second output node and a second low-side switch configured to be coupled between said second output node and ground;
the circuit comprising:
a measuring circuit configured to provide a first measure of a first operating characteristic of the high-side switch comprised in one of the first branch and the second branch of the full-bridge class-D amplifier, and a second measure of a second operating characteristic of the low-side switch comprised in the other of the first branch and the second branch of the full-bridge class-D amplifier;
a checking circuit configured to receive from the measuring circuit the first measure and the second measure and to determine an imbalance between said first measure and said second measure to provide an imbalance signal; and
a detection circuit configured to receive from the checking circuit said imbalance signal and to detect the presence of an electrical short circuit in response to said imbalance signal.

2. The circuit according to claim 1, wherein said checking circuit is configured to determine the imbalance between said first measure and said second measure by:
determining an absolute value of a difference between said first measure and said second measure;
checking whether said absolute value of the difference is higher than a threshold; and
providing the imbalance signal in response to the checking operation.

3. The circuit according to claim 1, wherein said first measure and said second measure are current-based measures, wherein:
said first measure is indicative of a current flowing in the high-side switch; and
said second measure is indicative of a current flowing in the low-side switch.

4. The circuit according to claim 1, wherein said measuring circuit comprises:
a first current sensor coupled to the first high-side switch and configured to sense a current flowing therein;
a second current sensor coupled to the second high-side switch and configured to sense a current flowing therein;
a third current sensor coupled to the first low-side switch and configured to sense a current flowing therein; and
a fourth current sensor coupled to the second low-side switch and configured to sense a current flowing therein; and
wherein said first measure is detected either via the first current sensor or the second current sensor and said second measure is detected either via the fourth current sensor or the third current sensor, respectively.

5. The circuit according to claim 4, wherein each current sensor of the first, second, third and fourth current sensors comprises an Analog-to-Digital Converter configured:
to sense a voltage proportional to the current flowing in the respective switch coupled to the current sensor;
to sense a reference voltage proportional to a maximum acceptable current flowing in a reference switch matched with said respective switch; and
to convert said sensed voltage in a digital value based on said sensed reference voltage, said digital value being the first measure or the second measure.

6. The circuit according to claim 1, wherein said measuring circuit comprises:
a high-side current sensor configured to be coupled either to the first high-side switch or the second high-side switch and to sense a current flowing in the coupled high-side switch; and
a low-side current sensor configured to be coupled either to the second low-side switch or the first low-side switch respectively, and to sense a current flowing in the coupled low-side switch; and
wherein said first measure is detected via the high-side current sensor and said second measure is detected via the low-side current sensor.

7. The circuit according to claim 6, wherein each current sensor of the high-side and low-side current sensors comprises comprise an Analog-to-Digital Converter configured:
to sense a voltage proportional to the current flowing in the respective switch coupled to the current sensor;
to sense a reference voltage proportional to a maximum acceptable current flowing in a reference switch matched with said respective switch; and
to convert said sensed voltage in a digital value based on said sensed reference voltage, said digital value being the first measure or the second measure.

8. The circuit according to claim 1, wherein said measuring circuit comprises a level-shifter configured:
to sense one voltage out of a voltage proportional to the current flowing in the high-side switch comprised in one of the first branch and the second branch of the full-bridge class-D amplifier and a voltage proportional to the current flowing in the low-side switch comprised in the other of the first branch and the second branch of the full-bridge class-D amplifier;
to level-shift said sensed voltage to a voltage level of the other voltage out of the voltage proportional to the current flowing in the high-side switch comprised in one of the first branch and the second branch of the full-bridge class-D amplifier and the voltage proportional to the current flowing in the low-side switch comprised in the other of the first branch and the second branch of the full-bridge class-D amplifier;
to provide said level-shifted sensed voltage as said first measure in response to the sensed voltage being the voltage proportional to the current flowing in the high-side switch comprised in one of the first branch and the second branch of the full-bridge class-D amplifier, the voltage proportional to the current flowing in the low-side switch comprised in the other of the first branch and the second branch of the full-bridge class-D amplifier being provided as the second measure; and
to provide the voltage proportional to the current flowing in the high-side switch comprised in one of the first branch and the second branch of the full-bridge class-D amplifier as the first measure in response to the sensed voltage being the voltage proportional to the current flowing in the low-side switch comprised in the other of the first branch and the second branch of the full-bridge class-D amplifier, said level-shifted sensed voltage being provided as the second measure.

9. The circuit according to claim 1, wherein said measuring circuit comprises:
a first level-shifter configured:
to sense a voltage proportional to the current flowing in said high-side switch comprised in one of the first branch and the second branch of the full-bridge class-D amplifier;
to level-shift said sensed voltage to a voltage level; and
to provide said level-shifted sensed voltage as said first measure; and
a second level-shifter configured:
to sense a voltage proportional to the current flowing in said low-side switch comprised in the other of the first branch and the second branch of the full-bridge class-D amplifier;
to level-shift said sensed voltage to said voltage level; and
to provide said level-shifted sensed voltage as said second measure.

10. The circuit according to claim 1, wherein said measuring circuit comprises:
a first branch current sensor coupled to the first output node and configured to sense a current flowing therein; and
a second branch current sensor coupled to the second output node and configured to sense a current flowing therein; and
wherein said first measure is detected via one current sensor out of the first branch current sensor and the second branch current sensor and said second measure is detected via the other current sensor out of the first branch current sensor and the second branch current sensor.

11. The circuit according to claim 10, wherein said first branch current sensor and said second branch current sensor are implemented via one of: shunt resistors, metal sensing, or Hall effect sensing.

12. The circuit according to claim 1, wherein:
said first measure and said second measure are time-based measures and wherein said first branch and said second branch of the full-bridge class-D amplifier are driven via respective drivers configured to receive respective driving signals; and
said first measure is indicative of a time delay from a rising edge of a driving signal provided to a driver configured to drive said high-side switch comprised in one of the first branch and the second branch of the full-bridge class-D amplifier to a corresponding rising edge of an output signal provided by said high-side switch; and
said second measure is indicative of a time delay from a falling edge of a driving signal provided to a driver configured to drive said low-side switch comprised in the other of the first branch and the second branch of the full-bridge class-D amplifier to a corresponding falling edge of an output signal provided by said low-side switch.

13. The circuit according to claim 12, wherein said measuring circuit comprises:
a first storing circuit configured to store said first measure; and
a second storing circuit configured to store said second measure; and
wherein said checking circuit is configured to receive the first measure and the second measure from said first storing circuit and said second storing circuit comprised in the measuring circuit, respectively.

14. The circuit according to claim 13, wherein:
the first storing circuit is a first capacitor configured to store a voltage indicative of the first measure;
the second storing circuit is a second capacitor configured to store a voltage indicative of the second measure; and
said checking circuit is configured to receive the voltage indicative of the first measure and the voltage indicative of the second measure from said first storing circuit and said second storing circuit comprised in the measuring circuit, respectively.

15. The circuit according to claim 12:
wherein said checking circuit is configured to determine the imbalance between said first measure and said second measure by:
determining an absolute value of a difference between said first measure and said second measure;
checking whether said absolute value of the difference is higher than a threshold; and
providing the imbalance signal in response to the checking operation; and
wherein said operation of determining the absolute value of the difference between said first measure and said second measure comprises:
pre-charging a capacitor to a reference voltage via a reference current;
charging said capacitor with said reference current to increase a capacitor voltage of a first voltage indicative of the first measure;
discharging said capacitor with said reference current to decrease said capacitor voltage of a second voltage indicative of the second measure; and
providing a first capacitor voltage equal to said capacitor voltage plus a margin and a second capacitor voltage equal to said capacitor voltage minus said margin as the absolute value of the difference between said first measure and said second measure; and
wherein said operation of checking whether said absolute value of the difference is higher than a threshold comprises checking whether said first capacitor voltage is lower than said voltage reference or said second capacitor voltage is higher than said voltage reference.

16. The circuit according to claim 15:
wherein said first voltage indicative of the first measure is obtained by:
converting the output signal provided by the high-side switch comprised in one of the first branch and the second branch of the full-bridge class-D amplifier in a first logic signal indicative of a time behavior of said output signal, preferably via a first comparator having a reference voltage threshold equal to half the supply voltage; and
converting said first logic signal in said first voltage indicative of the first measure, preferably by charging a first capacitor based on said first logic signal; and
wherein said second voltage indicative of the second measure is obtained by:
converting the output signal provided by the low-side switch comprised in the other of the first branch and the second branch of the full-bridge class-D amplifier in a second logic signal indicative of a time behavior of said output signal, preferably via a second comparator having a reference voltage threshold equal to half the supply voltage; and
converting said second logic signal in said second voltage indicative of the second measure, preferably by charging a second capacitor based on said second logic signal.

17. The circuit according to claim 12, wherein said checking circuit is configured to check for the presence of imbalance between said first measure and said second measure by:
verifying whether a logic signal assumes a logic level for a duration higher than a duration threshold; and
determining the presence of imbalance if the verifying operation indicates that the logic signal assumes said logic level for a duration higher than said duration threshold;
wherein the logic signal comprises one of:
a first logic signal indicative of a time behavior of the output signal provided by the high-side switch comprised in one of the first branch and the second branch of the full-bridge class-D amplifier, preferably obtained via a first comparator having a reference voltage threshold equal to half the supply voltage, said first logic signal being indicative of one of the first measure and the second measure, and
a second logic signal indicative of a time behavior of the output signal provided by the low-side switch comprised in the other of the first branch and the second branch of the full-bridge class-D amplifier, preferably obtained via a second comparator having a reference voltage threshold equal to half the supply voltage, said second logic signal being indicative of the other of the first measure and the second measure.

18. A method of detecting electrical short circuits in a full-bridge class-D amplifier, where the full-bridge class-D amplifier comprises: a first branch comprising a first high-side switch configured to be coupled between a supply voltage and a first output node and a first low-side switch configured to be coupled between said first output node and ground; and a second branch comprising a second high-side switch configured to be coupled between said supply voltage and a second output node and a second low-side switch configured to be coupled between said second output node and ground; the method comprising:
providing, via a measuring circuit, a first measure of a first operating characteristic of the high-side switch comprised in one of the first branch and the second branch of the full-bridge class-D amplifier;
providing, via the measuring circuit, and a second measure of a second operating characteristic of the low-side switch comprised in the other of the first branch and the second branch of the full-bridge class-D amplifier;
receiving, at a checking circuit, the first measure and the second measure from the measuring circuit;
determining, via the checking circuit, an imbalance between said first measure and said second measure and generating an imbalance signal;
receiving, at a detection circuit, said imbalance signal from the checking circuit; and
detecting, via the detection circuit, the presence of an electrical short circuit in response to said imbalance signal.
